(19) United States
(12) Patent Application Publication
(10) Pub. No.: US 2026/0235441 A1
(43) Pub. Date: Aug. 13, 2026

(54) IN FIELD WAVELENGTH CALIBRATION OF A WAVELENGTH SCALE OF A SPECTROMETER DEVICE

(71) Applicant: TRINAMIX GMBH, Ludwigshafen am Rhein (DE)

(72) Inventors: Szu-Yu HUANG, Ludwigshafen am Rhein (DE); Samiul ISLAM, Mannheim (DE); Henning ZIMMERMANN, Ludwigshafen am Rhein (DE); Felix SCHMIDT, Ludwigshafen am Rhein (DE); Celal Mohan OEGUEN, Ludwigshafen am Rhein (DE); Tobias BAUMGARTNER, Ludwigshafen am Rhein (DE); Till-Jonas OSTERMANN, Ludwigshafen am Rhein (DE); Bernd SCHERWATH, Ludwigshafen am Rhein (DE)

(21) Appl. No.: 19/155,080

(22) PCT Filed: Feb. 22, 2024
(86) PCT No.: PCT/EP24/54526

§ 371 Date: Aug. 8, 2025

(30) Foreign Application Priority Data
Feb. 23, 2023 (EP) 23158145.5

(51) Int. Cl. G01J 3/02; G01J 3/10

(52) U.S. Cl. CPC G01J 3/0297; G01J 3/10

(57) ABSTRACT

Disclosed herein is a spectrometer device for obtaining spectroscopic information on at least one object, the spectrometer device including:
i. at least one light source for generating illumination light for illuminating the object, the light source including at least one light-emitting diode and at least one luminescent material for light-conversion of primary light generated by the light-emitting diode;
ii. at least one detector for detecting light and, thereby, generating at least one detector signal; and
iii. at least one evaluation unit configured for deriving the spectroscopic information on the object from the at least one detector signal, wherein the evaluation unit is configured for deriving the spectroscopic information on the object by taking into consideration wavelength correction information.

### TECHNICAL FIELD

The invention relates to a spectrometer device for obtaining spectroscopic information on at least one object, specifically for analyzing a sample, to a method for calibrating a spectrometer device for obtaining spectroscopic information on at least one object, and a method of obtaining spectroscopic information on at least one object. The invention further relates to a computer program and to a non-transient computer-readable medium. Such devices and methods can, in general, be used for investigating or monitoring purposes, in particular, in the infrared (IR) spectral region, especially in the near-infrared (NIR) spectral region, and in the visible (VIS) spectral region, e.g. in a spectral region allowing to mimic a human's ability of color sight. However, further applications are feasible.

### BACKGROUND ART

Spectrometer devices are known to be efficient tools for obtaining information on the spectral properties of an object, when emitting, irradiating, reflecting and/or absorbing light. Spectrometer devices, thus, may assist in analyzing samples or other tasks in which information on the spectral properties of an object is of interest.

Usually, in spectrometer devices, spectral information is obtained via one or more detectors and one or more wavelength-selective optical elements, such as one or more dispersive optical elements, filters such as bandpass filters, prisms, gratings, interferometers, or the like. The detectors may comprise any type of light-sensitive element, such as one or more single or multiple pixel detectors, line detectors or array detectors having one- or two-dimensional arrays of pixels. Further, spectrometer devices may comprise one or more light sources. Thus, in spectroscopy, typically, tunable light sources, e.g. lasers, and/or broad-band emitting light sources are used, such as halogen-gas filled light bulbs and/or hot filaments. However, additionally or alternatively, other light sources, such as light emitting diodes have also been proposed for the visible spectral region.

Generally, for spectrometer devices, particularly spectrometer devices in the near-infrared, a calibration of the optical response is crucial for generating reliable spectroscopic information on an object. Calibration of an optical response, e.g. a responsivity of a detector and/or an optical system, may be performed out in field by using a reference measurement. Thereby, the vertical axis of a spectrum derived may be calibrated. The vertical axis, typically, comprises information on to the intensity for a specific wavelength. Generally, the calibration of the wavelength information required for generating the spectrum, which may then be considered as the x-axis of the optical spectrum, is performed at a factory, using light sources and/or reference samples with well-known optical spectra. The factory calibration of the wavelength information may become invalid, due to aging of the device (e.g. of the optical components). This may result in unpredictable systematic errors in the measurement results.

As an example, US 2010/208261 A1 describes a device for determining at least one optical property of a sample. The device comprises a tunable excitation light source for applying excitation light to the sample. The device furthermore comprises a detector for detecting detection light emerging from the sample. The excitation light source comprises a light-emitting diode array, which is configured at least partly as a monolithic light-emitting diode array. The monolithic light-emitting diode array comprises at least three light-emitting diodes each having a different emission spectrum.

U.S. Pat. No. 8,164,050 B2 describes a multi-channel source assembly for downhole spectroscopy that has individual sources that generate optical signals across a spectral range of wavelengths. A combining assembly optically combines the generated signals into a combined signal and a routing assembly that splits the combined signal into a reference channel and a measurement channel. Control circuitry electrically coupled to the sources modulates each of the sources at unique or independent frequencies during operation.

Further, U.S. Pat. No. 7,061,618 B2 describes integrated spectroscopy systems, wherein in some examples, integrated tunable detectors, using one or multiple Fabry-Perot tunable filters, are provided. Other examples use integrated tunable sources combining one or multiple diodes, such as superluminescent light emitting diodes (SLED), and a Fabry Perot tunable filter or etalon.

Furthermore, U.S. Pat. No. 5,475,221 A describes an optical device which uses an array of light emitting diodes, controlled by multiplexing schemes, to replace conventional broad band light sources in devices such as spectrometers.

Generally, spectrometer devices are subject to various internal and external influences, such as environmental influences, which may have an impact on the results of the spectroscopic measurements. In order to correct and/or compensate for these influences, various calibration and/or correction methods are known. These calibration methods may be performed once or several times, such as under laboratory conditions, e.g. by the manufacturer. However, also a plurality of on-line calibration techniques are known which may be performed by performing one or more correction and/or calibration steps in between two spectroscopic measurements or even during the measurements.

U.S. Ser. No. 09/360,366 B1 discloses a self-referencing spectrometer that simultaneously auto-calibrate and measure optical spectra of physical object utilizing shared aperture as optical inputs. The concurrent measure and self-calibrate capabilities makes it possible as an attachment spectrometer on a mobile computing device without requiring an off-line calibration with an external reference light source. Through the mobile computing device, the obtained spectral information and imagery captured can be distributed through the wireless communication networks.

DE 102014013848 B4 discloses a microspectrometer, in particular a NIR microspectrometer for mobile applications in battery-operated terminals, to overcome the nonminiaturization and handheld limitations of the aforementioned system configurations, a microspectrometer system, and a calibration method. The miniaturized NIR spectrometer is to be designed without active temperature stabilization. Instead, according to the invention, the spectral sensitivity function is recorded on several levels in the expected working temperature range as part of a factory temperature calibration step (QEλ=f(T); measured with an integrated temperature sensor).

WO 2019/191698 A2 relates to a self-referenced spectrometer for providing simultaneous measurement of a background or reference spectral density and a sample or other spectral density. The self-referenced spectrometer includes an interferometer optically coupled to receive an input beam and to direct the input beam along a first optical path to produce a first interfering beam and a second optical path to produce a second interfering beam, where each interfering beam is produced prior to an output of the interferometer. The spectrometer further includes a detector optically coupled to simultaneously detect a first interference signal produced from the first interfering beam and a second interference signal produced from the second interfering beam, and a processor configured to process the first interference signal and the second interference signal and to utilize the second interference signal as a reference signal in processing the first interference signal.

US 20210293620 A1 discloses a spectrometer, comprising: an illumination device for illuminating a spectrometric measurement region; a detection unit for detecting electromagnetic radiation coming from the spectrometric measurement region; and a spectral element, which is arranged in the beam path between the illumination device and the detection unit. The illumination device comprises: a light emitting diode having a first central wavelength, which is designed to emit first electromagnetic radiation having a first spectrum; and a luminescent element for converting a first component of the first electromagnetic radiation having the first spectrum into second electromagnetic radiation having a second spectrum. The first central wavelength is 550 nm or 3000 nm or has a value between 550 nm and 3000 nm. The first spectrum and the second spectrum have an overlap.

U.S. Ser. No. 06/667,802 B2 discloses a method of calibrating a spectrographic inspection system. The method comprises providing a plurality of packages, each of the plurality of packages containing a group of items, wherein each of the groups of items has a known composition, measuring the reflectance value of each of the groups of items and thereby obtaining a reference reflectance value set, normalizing the reference reflectance value set and thereby creating a normalized reference reflectance value set, and storing the normalized reference reflectance value set.

U.S. Ser. No. 06/717,669 B2 discloses auto-calibrating spectrometers and methods that measure transmission or reflection versus wavelength of a sample without need for calibration for long periods of time. Reflection and transmission spectrometers along with auto-calibrating methods for use therewith are disclosed. Light is focused onto a sample using a lens or similar optical element that transmits light towards the sample reflects light impinging upon it, and transmits light reflected from the sample. If one monitors the light reflected from the first lens and sample, very useful information is available related to the system response versus time. The reflected light is monitored from the first lens and sample, and the system changes over time are corrected for using this reflected light.

U.S. Ser. No. 09/448,114 B2 discloses a spectrometer which comprises a plurality of isolated optical channels comprising a plurality of isolated optical paths. The isolated optical paths decrease crosstalk among the optical paths and allow the spectrometer to have a decreased length with increased resolution. In many embodiments, the isolated optical paths comprise isolated parallel optical paths that allow the length of the device to be decreased substantially. In many embodiments, each isolated optical path extends from a filter of a filter array, through a lens of a lens array, through a channel of a support array, to a region of a sensor array. Each region of the sensor array comprises a plurality of sensor elements in which a location of the sensor element corresponds to the wavelength of light received based on an angle of light received at the location, the focal length of the lens and the central wavelength of the filter.

US 2013/0093936 A1 discloses an energy dispersion device, spectrograph and method that can be used to evaluate the composition of matter on site without the need for specialized training or expensive equipment. The energy dispersion device or spectrograph can be used with a digital camera or cell phone. A device of the invention includes a stack of single- or double-dispersion diffraction gratings that are rotated about their normal giving rise to a multiplicity of diffraction orders from which meaningful measurements and determinations can be made with respect to the qualitative or quantitative characteristics of matter.

US 2017/0153142 A1 discloses spectrometer methods and apparatus providing improved accuracy and better accommodation variability among spectrometer systems and associated components. In many instances one or more of a calibration cover, an accessory, or a spectrometer are each associated with a unique identifier and corresponding calibration data. The calibration data associated with the unique identifiers can be stored in a database used to determine spectral information from measurements of objects obtained with individual spectrometer devices. The spectrum of the object can be determined in response to the unique identifiers and associated calibration data in order to provide improved accuracy and decreased cost.

Despite the advantages achieved by known methods and devices, several technical challenges remain in the field of spectroscopy and spectroscopic devices, specifically for spectroscopy in the near-infrared range. Thus, specifically, calibration techniques correcting for various influences are desirable, specifically for on-line correction of these influences in the field, at the location of the spectroscopic measurement. Specifically, the temperature is known to have a significant impact on the results and the precision of the spectroscopic measurements. Temperature changes may arise due to external influences, such as to changes of the environmental temperature. Additionally or alternatively, temperature changes may arise due to internal influences, such as electrical currents and electrical resistances within the spectroscopic devices, e.g. due to electrical power dissipation. These temperature changes may arise on a short timescale and/or may arise in the form of long-term drifts. Further, it has to be taken into account that temperature changes do not necessarily have to take place on a global scale and/or with the entire spectrometer device being at a thermal equilibrium. Thus, local temperature changes may occur, specifically at locations which are difficult to monitor, such as at locations within the spectrometer device and/or at interfaces within components of the spectrometer device, e.g. at semiconductor interfaces. In addition, temperature dependency of the system may change. For example, the system may exhibit a different behavior after some time, even if the temperature remains constant, e.g. due to degradation, aging, or changes of the optical or electrical interfaces due to frequent usage.

### Problem to be Solved

It is therefore desirable to provide methods and devices, which at least partially address the above-mentioned technical challenges and at least substantially avoid the disadvantages of known methods and devices. In particular, it is an object of the present invention to provide a spectrometer device and methods which are capable of, particularly in-field, correcting for external and/or internal influences on the wavelength information required for generating spectroscopic information on the object.

### SUMMARY

This problem is addressed by a spectrometer device for obtaining spectroscopic information on at least one object, a corresponding method, a method for calibrating a spectrometer device for obtaining spectroscopic information on at least one object, a computer program and a non-transient computer-readable medium, with the features of the independent claims. Advantageous embodiments which might be realized in an isolated fashion or in any arbitrary combinations are listed in the dependent claims as well as throughout the specification.

In a first aspect, a spectrometer device for obtaining spectroscopic information on at least one object is disclosed. The spectrometer device comprises:
i. at least one light source for generating illumination light for illuminating the object, the light source comprising at least one light-emitting diode and at least one luminescent material for light-conversion of primary light generated by the light-emitting diode;
ii. at least one detector for detecting detection light from the object generated by the at least one light source and, thereby, generating at least one detector signal;
iii. at least one evaluation unit configured for deriving the spectroscopic information on the object from the at least one detector signal, wherein the evaluation unit is configured for deriving the spectroscopic information on the object by taking into consideration wavelength correction information, particularly derived from the at least one detector signal.

The term “spectrometer device” as used herein is a broad term and is to be given its ordinary and customary meaning to a person of ordinary skill in the art and is not to be limited to a special or customized meaning. The term specifically may refer, without limitation, to an optical device configured for acquiring at least one item of spectral information on at least one object. Specifically, the at least one item of spectral information may refer to at least one optical property or optically measurable property which is determined as a function of a wavelength, for one or more different wavelengths. More specifically, the optical property or optically measurable property, as well as the at least one item of spectral information, may relate to at least one property characterizing at least one of a transmission, an absorption, a reflection and an emission of the at least one object, either by itself or after illumination with external light. The at least one optical property may be determined for one or more wavelengths. The spectrometer device specifically may form an apparatus which is capable of recording a signal intensity with respect to the corresponding wavelength of a spectrum or a partition thereof, such as a wavelength interval, wherein the signal intensity may, specifically, be provided as an electrical signal which may be used for further evaluation.

The spectrometer device, as an example, may be or may comprise a device which allows for a measurement of at least one spectrum, e.g. for the measurement of a spectral flux, specifically as a function of a wavelength or detection wavelength. The spectrum may be acquired, as an example, in absolute units or in relative units, e.g. in relation to at least one reference measurement. Thus, as an example, the acquisition of the at least one spectrum specifically may be performed either for a measurement of the spectral flux (unit W/nm) or for a measurement of a spectrum relative to at least one reference material (unit 1), which may describe the property of a material, e.g., reflectance over wavelength. Additionally or alternatively, the reference measurement may be based on a reference light source, an optical reference path, a calculated reference signal, e.g. a calculated reference signal from literature, and/or on a reference device.

Specifically, the at least one spectrometer device may be a diffusive reflective spectrometer device configured for acquiring spectral information from the light which is diffusively reflected by the at least one object, e.g. the at least one sample. Additionally or alternatively, the at least one spectrometer device may be or may comprise an absorption- and/or transmission spectrometer. In particular, measuring a spectrum with the spectrometer device may comprise measuring absorption in a transmission configuration. Specifically, the spectrometer device may be configured for measuring absorption in a transmission configuration. As outlined above, however, other types of spectrometer devices are also feasible.

The at least one spectrometer device, specifically and as will be outlined in further detail below, may comprise at least one light source which, as an example, may be at least one of a tunable light source, a light source having at least one fixed emission wavelength and a broadband light source. The spectrometer device, as will be outlined in further detail below, further comprises at least one detector device configured for detecting light, such as light which is at least one of transmitted, reflected or emitted from the at least one object. The spectrometer device further may comprise, as will be outlined in further detail below, at least one wavelength-selective element, such as at least one of a grating, a prism and a filter, e.g. a length variable filter having varying transmission properties over its lateral extension. The wavelength-selective element may be used for separating incident light into a spectrum of constituent wavelength signals whose respective intensities are determined by employing a detector such as a detector having a detector array as described below in more detail.

The spectrometer device, specifically, may be a portable spectrometer device. The term “portable” as used herein is a broad term and is to be given its ordinary and customary meaning to a person of ordinary skill in the art and is not to be limited to a special or customized meaning. The term specifically may refer, without limitation, to the property of at least one object of being moved by human force, such as by a single user. Specifically, the object characterized by the term “portable” may have a weight not exceeding 10 kg, specifically not exceeding 5 kg, more specifically not exceeding 1 kg or even not exceeding 500 g. Additionally or alternatively, the dimensions of the object characterized by the term “portable” may be such that the object extends by no more than 0.3 m into any dimension, specifically by no more than 0.2 m into any dimension. The object, specifically, may have a volume of no more than 0.03 m³, specifically of no more than 0.01 m³, more specifically no more than 0.001 m³ or even no more than 500 mm³. In particular, as an example, the portable spectrometer device may have dimensions of e.g. 10 mm by 10 mm by 5 mm. Specifically, the portable spectrometer device may be part of a mobile device or may be attachable to a mobile device, such as a notebook computer, a tablet, a cell phone, such as a smart phone, a smartwatch and/or a wearable computer, also referred to as “wearable”, e.g. a body borne computer such as a wrist band or a watch. In particular, the a weight of the spectrometer device, specifically the portable spectrometer device, may be in the range from 1 g to 100 g, more specifically in the range from 1 g to 10 g.

The term “spectroscopic information”, also referred to as “spectral information” or as “an item of spectral information”, as used herein is a broad term and is to be given its ordinary and customary meaning to a person of ordinary skill in the art and is not to be limited to a special or customized meaning. The term specifically may refer, without limitation, to an item of information, e.g. on at least one object and/or radiation emitted by at least one object, characterizing at least one optical property of the object, more specifically at least one item of information characterizing, e.g. qualifying and/or quantifying, at least one of a transmission, an absorption, a reflection and an emission of the at least one object. As an example, the at least one item of spectral information may comprise at least one intensity information, e.g. information on an intensity of light being at least one of transmitted, absorbed, reflected or emitted by the object, e.g. as a function of a wavelength or wavelength sub-range over one or more wavelengths, e.g. over a range of wavelengths. Specifically, the intensity information may correspond to or be derived from the signal intensity, specifically the electrical signal, recorded by the spectrometer device with respect to a wavelength or a range of wavelengths of the spectrum.

The spectrometer device specifically may be configured for acquiring at least one spectrum or at least a part of a spectrum of detection light propagating from the object to the spectrometer.

The spectrum may describe the radiometric unit of spectral flux, e.g. given in units of watt per nanometer (W/nm), or other units, e.g. as a function of the wavelength of the detection light. Thus, the spectrum may describe the optical power of light, e.g. in the NIR spectral range, in a specific wavelength band. The spectrum may contain one or more optical variables as a function of the wavelength, e.g. the power spectral density, electric signals derived by optical measurements and the like. The spectrum may indicate, as an example, the power spectral density and/or the spectral flux of the object, e.g. of a sample, e.g. relative to a reference sample, such as a transmittance and/or a reflectance of the object, specifically of the sample.

The spectrum, as an example, may comprise at least one measurable optical variable or property of the detection light and/or of the object, specifically as a function of the illumination light and/or the detection light. As an example, the at least one measurable optical variable or property may comprise at least one at least one radiometric quantity, such as at least one of a spectral density, a power spectral density, a spectral flux, a radiant flux, a radiant intensity, a spectral radiant intensity, an irradiance, a spectral irradiance. Specifically, as an example, the spectrometer device, specifically the detector, may measure the irradiance in Watt per square meter (W/m²), more specifically the spectral irradiance in Watt per square meter per nanometer (W/m²/nm). Based on the measured quantity the spectral flux in Watt per nanometer (W/nm) and/or the radiant flux in Watt (W) may be determined, e.g. calculated, by taking into account an area of the detector.

The term “object” as used herein is a broad term and is to be given its ordinary and customary meaning to a person of ordinary skill in the art and is not to be limited to a special or customized meaning. The term specifically may refer, without limitation, to an arbitrary body, chosen from a living object and a non-living object. Thus, as an example, the at least one object may comprise one or more articles and/or one or more parts of an article, wherein the at least one article or the at least one part thereof may comprise at least one component which may provide a spectrum suitable for investigations. Additionally or alternatively, the object may be or may comprise one or more living beings and/or one or more parts thereof, such as one or more body parts of a human being, e.g. a user, and/or an animal. The object specifically may comprise at least one sample which may fully or partially be analyzed by spectroscopic methods. As an example, the object may be or may comprise at least one of: human or animal skin; edibles, such as fruits; plastics and textile.

The spectrometer comprises at least one light source for generating illumination light for illuminating the object, the light source comprising at least one light-emitting diode and at least one luminescent material for light-conversion of primary light generated by the light-emitting diode.

As further used herein, the term “light” as used herein is a broad term and is to be given its ordinary and customary meaning to a person of ordinary skill in the art and is not to be limited to a special or customized meaning. The term specifically may refer, without limitation, to electromagnetic radiation in one or more of the infrared, the visible and the ultraviolet spectral range.

Herein, the term “ultraviolet spectral range”, generally, refers to electromagnetic radiation having a wavelength of 1 nm to 380 nm, preferably of 100 nm to 380 nm. Further, in partial accordance with standard ISO-21348 in a valid version at the date of this document, the term “visible spectral range”, generally, refers to a spectral range of 380 nm to 760 nm. The term “infrared spectral range” (IR) generally refers to electromagnetic radiation of 760 nm to 1000 μm, wherein the range of 760 nm to 1.5 μm is usually denominated as “near infrared spectral range” (NIR) while the range from 1.5μ to 15 μm is denoted as “mid infrared spectral range” (MidIR) and the range from 15 μm to 1000 μm as “far infrared spectral range” (FIR). Preferably, light used for the typical purposes of the present invention is light in the infrared (IR) spectral range, more preferred, in the near infrared (NIR) and/or the mid infrared spectral range (MidIR), especially the light having a wavelength of 1 μm to 5 μm, preferably of 1 μm to 3 μm. This is due to the fact that many material properties or properties on the chemical constitution of many objects may be derived from the near infrared spectral range. It shall be noted, however, that spectroscopy in other spectral ranges is also feasible and within the scope of the present invention.

Consequently, the term “light source”, also referred to as an “illumination source”, as used herein is a broad term and is to be given its ordinary and customary meaning to a person of ordinary skill in the art and is not to be limited to a special or customized meaning. The term specifically may refer, without limitation, to an arbitrary device configured for generating or providing light in the sense of the above-mentioned definition. The light source specifically may be or may comprise at least one electrical light source, such as an electrically driven light source.

As will be outlined in further detail below, the light source generally can be embodied in various ways. Thus, the light source can be for example part of the spectrometer device in a housing of the spectrometer device. Alternatively or additionally, however, the at least one light source can also be arranged outside a housing, for example as a separate light source. The light source can be arranged separately from the object and illuminate the object from a distance.

In spectroscopy, various sources and paths of light are to be distinguished. In the context of the present invention, a nomenclature is used which, firstly, denotes light propagating from the light source to the object as “illuminating light” or “illumination light”. Secondly, light propagating from the object to the detector is denoted as “detection light”. The detection light may comprise at least one of illumination light reflected by the object, illumination light scattered by the object, illumination light transmitted by the object, luminescence light generated by the object, e.g. phosphorescence or fluorescence light generated by the object after optical, electrical or acoustic excitation of the object by the illumination light or the like. Thus, the detection light may directly or indirectly be generated through the illumination of the object by the illumination light.

Further, as will be outlined in detail below, within the light source itself, a distinction may be made between various light sources, such as primary light sources and secondary light sources. Thus, as will be outlined in further detail below, “primary light”, also referred to as “pump light”, may be generated by a primary light source such as at least one light-emitting diode and may subsequently be transformed into “secondary light”, such as by using light conversion, e.g. through one or more phosphor materials. The illumination light may be or may comprise at least one of the primary light or a part thereof, the secondary light or a part thereof, or a mixture of both.

Consequently, the term “illuminate”, as used herein, is a broad term and is to be given its ordinary and customary meaning to a person of ordinary skill in the art and is not to be limited to a special or customized meaning. The term specifically may refer, without limitation, to the process of exposing at least one element to light.

As outlined above, the light source comprises at least one light-emitting diode and at least one luminescent material for light-conversion of primary light generated by the light-emitting diode, wherein, specifically, the illumination light may be a combination of the primary light and light generated by the light-conversion by the luminescent material or light generated by the light conversion of the luminescent material, also referred to as secondary light.

The term “light-emitting diode” or briefly “LED”, as used herein, is a broad term and is to be given its ordinary and customary meaning to a person of ordinary skill in the art and is not to be limited to a special or customized meaning. The term specifically may refer, without limitation, to an optoelectronic semiconductor device capable of emitting light when an electrical current flows through the device. The optoelectronic semiconductor device may be configured for generating the light due to various physical processes, including one or more of spontaneous emission, induced emission, decay of metastable excited states and the like. Thus, as an example, the light-emitting diode, may comprise one or more of: a light-emitting diode based on spontaneous emission of light, in particular an organic light emitting diode, a light-emitting diode based on superluminescence (sLED), or a laser diode (LD) In the following, without narrowing the possible embodiments of the light-emitting diode to any of the before-mentioned physical principles or setups, the abbreviation “LED” will be used for any type of light-emitting diode. Specifically, the LED may comprise at least two layers of semiconductor material, wherein light may be generated at at least one interface between the at least two layers of semiconductor material, specifically due to a recombination of positive and negative electrical charges, e.g. due to electronhole recombination. The at least two layers of semiconductor material may have differing electrical properties, such as at least one of the layers being an n-doped semiconductor material and at least one of the layers being a p-doped semiconductor material. Thus, as an example, the LED may comprise at least one pn-junction and/or at least one pin-set up. It shall be noted, however, that other device structures are feasible, too. The at least one semiconductor material may specifically be or may comprise at least one inorganic semiconducting material. It shall be noted, however, that organic semiconducting materials may be used additionally or alternatively.

Generally, the LED may convert electrical current into light, specifically into the primary light, more specifically into blue primary light, as will be outlined in further detail below. The LED, thus, specifically may be a blue LED. The LED may be configured for generating the primary light, also referred to as the “pump light”. Thus, the LED may also be referred to as the “pump LED”. The LED specifically may comprise at least one LED chip and/or at least one LED die. Thus, the semiconductor element of the LED may comprise an LED bare chip.

Various types of LEDs suitable for generating the primary light are known to the skilled person and may also be applied in the present invention. Specifically, p-n-diodes may be used. As an example, one or more LEDs selected from the group of an LED on the basis of indium gallium nitride (InGaN), an LED on the basis of GaN, an LED on the basis of InGaN/GaN alloys or combinations thereof and/or other LEDs may be used. Additionally or alternatively, quantum well LEDs may also be used, such as one or more quantum well LEDs on the basis of InGaN. Additionally or alternatively, Superluminescence LEDs (sLED) and/or Quantum cascade lasers may be used.

The term “luminescence” as used herein is a broad term and is to be given its ordinary and customary meaning to a person of ordinary skill in the art and is not to be limited to a special or customized meaning. The term specifically may refer, without limitation, to the process of spontaneous emission of light by a substance not resulting from heat. Specifically, luminescence may refer to a cold-body radiation. More specifically, the luminescence may be initiated or excited by irradiation of light, in which case the luminescence is also referred to as “photoluminescence”. The property of a material being capable of performing luminescence, in the context of the present invention, is referred to by the adjective “luminescent”. The at least one luminescent material specifically may be a photoluminescent material, i.e. a material which is capable of emitting light after absorption of photons or excitation light. Specifically, the luminescent material may have a positive Stokes shift, which generally may refer to the fact that the secondary light is red-shifted with respect to the primary light.

The at least one luminescent material, thus, may form at least one converter, also referred to as a light converter, transforming primary light into secondary light having different spectral properties as compared to the primary light. Specifically, a spectral width of the secondary light may be larger than a spectral width of the primary light, and/or a center of emission of the secondary light may be shifted, specifically red-shifted, compared to the primary light. Specifically, the at least one luminescent material may have an absorption in the ultraviolet and/or blue spectral range and an emission in the near-infrared and/or infrared spectral range. Thus, generally, the luminescent material or converter may form at least one component of the phosphor LED converging primary light or pump light, specifically in the blue spectral range, into light having a longer wavelength, e.g. in the near-infrared or infrared spectral range.

Various types of conversion and/or luminescence are known and may be used in the context of the present invention. Thus, specifically, the conversion can occur via a dipole-allowed transition in the luminescent material, also referred to as fluorescence, and/or via a dipole-forbidden, thus long-lived, transition in the luminescent material, often also referred to as phosphorescence.

The luminescent material, specifically, may, thus, form at least one converter or light converter. The luminescent material may form at least one of a converter platelet, a luminescent and specifically a fluorescent coating on the LED and phosphor coating on the LED. The luminescent material may, as an example, comprise one or more of the following materials: Cerium-doped YAG (YAG:Ce³⁺, or Y₃Al₅O₁₂:Ce³⁺); rare-earth-doped Sialons; copper- and aluminium-doped zinc sulfide (ZnS:Cu,Al).

The LED and the luminescent material, together, may form a so-called “phosphor LED”. Consequently, the term “phosphor light-emitting diode” or briefly “phosphor LED”, as used herein, is a broad term and is to be given its ordinary and customary meaning to a person of ordinary skill in the art and is not to be limited to a special or customized meaning. The term specifically may refer, without limitation, to a combination of at least one light-emitting diode configured for generating primary light or pump light, and at least one luminescent material, also referred to as a “phosphor”, configured for light-conversion of the primary light generated by the light-emitting diode. The phosphor LED may form a packaged LED light source, including the LED die, e.g. a blue LED emitting blue pump light, as well as the phosphor, which, as an example, fully or partially coats the LED, which is, as an example, configured for converting the primary light or blue light into light having differing spectral properties, specifically into near-infrared light. Generally, the phosphor LED may be packaged in one housing or may be unpackaged. Thus, the LED and the at least one luminescent material for light-conversion of the primary light generated by the light-emitting diode may specifically be housed in a common housing. Alternatively, however, the LED may also be an unhoused or bare LED which may fully or partially be covered with the luminescent material, such as by disposing one or more layers of the luminescent material on the LED die. The phosphor LED, generally, may form an emitter or light source by itself.

In the light source, specifically the phosphor LED, the at least one luminescent material specifically may be located with respect to the light-emitting diode such that a heat transfer from the light-emitting diode to the luminescent material is possible. More specifically, the luminescent material may be located such that a heat transfer by one or both of thermal radiation and heat conduction is possible, more preferably by heat conduction. Thus, as an example, the luminescent material may be in thermal contact and/or in physical contact with the light-emitting diode. As an example, the luminescent material may form one or more coatings or layers in contact with or in close proximity to the light-emitting diode, such as with one or more of the semiconductor materials of the light-emitting diode. Thereby, generally, a temperature of the luminescent material and a temperature of the light-emitting diode may be coupled.

The at least one luminescent material specifically may form at least one layer. Generally, various alternatives of positioning the luminescent material with respect to the light-emitting diode are feasible, alone or in combination. Firstly, the luminescent material, e.g., at least one layer of the luminescent material, such as the phosphor, may be positioned directly on the light-emitting diode, which is also referred to as a “direct attach”, e.g. with no material in between the LED and the luminescent material or with one or more transparent materials in between, such as with one or more transparent materials, specifically transparent for the primary light, in between the LED and the luminescent material. Thus, as an example, a coating of the luminescent material may be placed directly or indirectly on the LED. Additionally or alternatively, the luminescent material, as an example, may form at least one converter body, such as at least one converter disk, which may be placed on top of the LED, e.g. by adhesive attachment of the converter body to the LED. Additionally or alternatively, the luminescent material may also be placed in a remote fashion, such that the primary light from the LED has to pass an intermediate optical path before reaching the luminescent material. This placement may also be referred to as a “remote placement” or as a “remote phosphor”. Again, as an example, the luminescent material in the remote placement may form a solid body or converter body, such as a disk or converter disk. Further, in case of the remote placement, the luminescent material may also be a coating. In particular, an object which is transmitting light, e.g. a thin glass substrate, module window, comprising and/or being made of glass or plastics, may be coated with the phosphor. Alternatively, a reflective surface may be coated with the phosphor. This could be a flat or rough mirror, which may comprise and/or be made of a high-reflective index material substrate, e.g. silicon, or a gold, silver, aluminum or chromium coated flat or rough surface, e.g. glass, or a plastic. In the intermediate optical path, one or more optical elements may be placed, such as one or more of a lens, a prism, a grating, a mirror, an aperture or a combination thereof. Thus, specifically, an optical system having imaging properties may be placed in between the LED and the luminescent material, in the intermediate optical path. Thereby, as an example, the primary light may be focused, or bundled onto the converter body.

The at least one spectrometer device may comprise at least one driving unit for electrically driving the light source. The term “to drive” as used herein is a broad term and is to be given its ordinary and customary meaning to a person of ordinary skill in the art and is not to be limited to a special or customized meaning. The term specifically may refer, without limitation, to the process of providing one or both of at least one control parameter and/or electrical power to another device. Consequently, the term “driving unit” as used herein is a broad term and is to be given its ordinary and customary meaning to a person of ordinary skill in the art and is not to be limited to a special or customized meaning. The term specifically may refer, without limitation, to an arbitrary device or a combination of devices configured for providing one or both of at least one control parameter and/or electrical power to another device, such as, in the present case, to the at least one light source. For example, the driving unit specifically may be configured for at least one of measuring and controlling one or more electrical parameters of an electrical power provided to the light source, specifically to the at least one light-emitting diode. As an example, the driving unit may be configured for providing an electrical current to the LED, specifically for controlling an electrical current through the LED. Therein, as an example, the driving unit may be configured for adapting and measuring a voltage provided to the LED, the voltage being required for achieving a specific electrical current through the LED. The measurement unit, e.g. the driving unit, specifically, may comprise one or more of: a current source, a voltage source, a current measurement device, such as an Ampere-meter, a voltage measurement device, such as a Volt-meter, a power measurement device. Specifically, the driving unit may comprise at least one current source for providing at least one predetermined current to the LED, wherein the current source specifically may be configured for adjusting or controlling a voltage applied to the LED in order to generate the predetermined current. The driving unit, as an example, may comprise one or more electrical components, such as integrated circuits, for driving the light source. The driving unit may fully or partially be integrated into the light source or may be separated from the light source.

As further outlined above, the spectrometer device comprises at least one detector for detecting detection light from the object generated by the at least one light source and, thereby, generating at least one detector signal.

The verb “to detect” as used herein is a broad term and is to be given its ordinary and customary meaning to a person of ordinary skill in the art and is not to be limited to a special or customized meaning. The term specifically may refer, without limitation, to the process of at least one of determining, measuring and monitoring at least one parameter, qualitatively and/or quantitatively, such as at least one of a physical parameter, a chemical parameter and a biological parameter. Specifically, the physical parameter may be or may comprise an electrical parameter. Consequently, the term “detector” as used herein is a broad term and is to be given its ordinary and customary meaning to a person of ordinary skill in the art and is not to be limited to a special or customized meaning. The term specifically may refer, without limitation, to an arbitrary device configured for detecting, i.e. for at least one of determining, measuring and monitoring, at least one parameter, qualitatively and/or quantitatively, such as at least one of a physical parameter, a chemical parameter and a biological parameter. The detector may be configured for generating at least one detector signal, more specifically at least one electrical detector signal, such as an analogue and/or a digital detector signal, the detector signal providing information on the at least one parameter measured by the detector. The detector signal may directly or indirectly be provided by the detector to the evaluation unit, such that the detector and the evaluation unit may be directly or indirectly connected. The detector signal may be used as a “raw” detector signal and/or may be processed or preprocessed before further used, e.g. by filtering and the like. Thus, the detector may comprise at least one processing device and/or at least one preprocessing device, such as at least one of an amplifier, an analogue/digital converter, an electrical filter and a Fourier transformation.

In the present case, the detector is configured for detecting light, such as, but not limited to, illumination light from the light source, and/or detection light from the object; and/or light from at least one reference target. Light propagating from the object to the spectrometer device or more specifically to the detector of the spectrometer device, which, according to the above-mentioned nomenclature, is referred to as “detection light”.

Thus, specifically, the detector may be or may comprise at least one optical detector. The optical detector may be configured for determining at least one optical parameter, such as an intensity and/or a power of light by which at least one sensitive area of the detector is irradiated. More specifically, the optical detector may comprise at least one photosensitive element and/or at least one optical sensor, such as at least one of a photodiode, a photocell, a photosensitive resistor, a phototransistor, a thermophile sensor, a photoacoustic sensor, a pyroelectric sensor, a photomultiplier and a bolometer. The detector, thus, may be configured for generating at least one detector signal, more specifically at least one electrical detector signal, in the above-mentioned sense, providing information on at least one optical parameter, such as the power and/or intensity of light by which the detector or a sensitive area of the detector is illuminated.

The detector may comprise one single optically sensitive element or area or a plurality of optically sensitive elements or areas. Specifically, the detector may be or may comprise at least one detector array, more specifically an array of photosensitive elements, as will be outlined in further detail below. Each of the photosensitive elements may comprise at least a photosensitive area which may be adapted for generating an electrical signal depending on the intensity of the incident light, wherein the electrical signal may, in particular, be provided to the evaluation unit, as will be outlined in further detail below.

The photosensitive area as comprised by each of the optically sensitive elements may, especially, be a single, uniform photosensitive area which is configured for receiving the incident light which impinges on the individual optically sensitive elements. However, other arrangements of the optically sensitive elements may also be conceivable.

The array of optically sensitive elements may be designed to generate detector signals, preferably electronic signals, associated with the intensity of the incident light which impinges on the individual optically sensitive elements. The detector signal may be an analogue and/or a digital signal. The electronic signals for adjacent pixelated sensors can, accordingly, be generated simultaneously or else in a temporally successive manner. By way of example, during a row scan or line scan, it is possible to generate a sequence of electronic signals which correspond to the series of the individual optically sensitive elements which are arranged in a line. In addition, the individual optically sensitive elements may, preferably, be active pixel sensors which may be adapted to amplify the electronic signals prior to providing it to the evaluation unit. For this purpose, the detector may comprise one or more signal processing devices, such as one or more filters and/or analogue-digital-converters for processing and/or preprocessing the electronic signals.

In case the detector comprises an array of optically sensitive elements, the detector, as an example, may be selected from any known pixel sensor, in particular, from a pixelated organic camera element, preferably, a pixelated organic camera chip, or from a pixelated inorganic camera element, preferably, a pixelated inorganic camera chip, more preferably from a CCD chip or a CMOS chip, which are, commonly, used in various cameras nowadays. As an alternative, the detector generally may be or comprise a photoconductor, in particular an inorganic photoconductor, especially PbS, PbSe, Ge, InGaAs, ext. InGaAs, InSb, or HgCdTe. As a further alternative it may comprise at least one of pyroelectric, bolometer or thermophile detector elements. Thus, a camera chip having a matrix of 1×N pixels or of M×N pixels may be used here, wherein, as an example, M may be <10 and N may be in the range from 1 to 50, preferably from 2 to 20, more preferred from 5 to 10. Further, a monochrome camera element, preferably a monochrome camera chip, may be used, wherein the monochrome camera element may be differently selected for each optically sensitive element, especially, in accordance with the varying wavelength along the series of the optical sensors.

Thus, the array may be adapted to provide a plurality of the electrical signals which may be generated by the photosensitive areas of the optically sensitive elements comprised by the array. The electrical signals as provided by the array of the spectrometer device may be forwarded to the evaluation unit.

As described above, the at least one evaluation unit is configured for deriving the spectroscopic information on the object from the at least one detector signal, wherein the evaluation unit is configured for deriving the spectroscopic information on the object by taking into consideration wavelength correction information, particularly derived from the at least one detector signal.

As further described above, the spectrometer device comprises the at least one evaluation unit for evaluating at least one detector signal generated by the detector and for deriving the spectroscopic information on the object from the detector signal. The term “to evaluate”, as used herein, is a broad term and is to be given its ordinary and customary meaning to a person of ordinary skill in the art and is not to be limited to a special or customized meaning. The term specifically may refer, without limitation, to the process of processing at least one first item of information in order to generate at least one second item of information thereby. Consequently, the term “evaluation unit”, as used herein, is a broad term and is to be given its ordinary and customary meaning to a person of ordinary skill in the art and is not to be limited to a special or customized meaning. The term specifically may refer, without limitation, to an arbitrary device or a combination of devices configured to evaluate or process at least one first item of information, in order to generate at least one second item of information thereof. Thus, specifically, the evaluation unit may be configured for processing at least one input signal and to generate at least one output signal thereof. The at least one input signal, as an example, may comprise at least one detector signal provided directly or indirectly by the at least one detector and, additionally, at least one signal directly or indirectly provided by the measurement unit, which may e.g. be an element of the driving unit, the signal comprising the at least one item of information on the at least one electrically measureable quantity, in particular the forward voltage.

As an example, the evaluation unit may be or may comprise one or more integrated circuits, such as one or more application-specific integrated circuits (ASICs), and/or one or more data processing devices, such as one or more of computers, digital signal processors (DSP), field programmable gate arrays (FPGA) preferably one or more microcomputers and/or microcontrollers. Additional components may be comprised, such as one or more preprocessing devices and/or data acquisition devices, such as one or more devices for receiving and/or preprocessing of the detector signals, such as one or more AD-converters and/or one or more filters. Further, the evaluation unit may comprise one or more data storage devices. Further, the evaluation unit may comprise one or more interfaces, such as one or more wireless interfaces and/or one or more wire-bound interfaces.

The at least one evaluation unit may be adapted to execute at least one computer program, such as at least one computer program performing or supporting the step of generating the items of information. As an example, one or more algorithms may be implemented which, by using the at least one detector signal and the at least one item of information on the at least one electrically measureable quantity, in particular the forward voltage, as input variables, may perform a predetermined transformation for deriving the spectroscopic information on the object, such as for deriving a corrected spectrum and/or for deriving at least one spectroscopic information describing at least one property of the object. For this purpose, the evaluation unit may, particularly, comprise at least one data processing device, also referred to as a processor, in particular an electronic data processing device, which can be designed to generate the desired information by evaluating the detector signal and the item of information on the at least one electrically measureable quantity, in particular the forward voltage. The evaluation unit may use an arbitrary process for generating the required information, such as by calculation and/or using at least one stored and/or known relationship. The evaluation unit specifically may be configured for performing at least one digital signal processing (DSP) technique on the primary detector signal or any secondary detector signal derived thereof, in particular at least one Fourier transformation. Additionally or alternatively, the evaluation unit may be configured for performing one or more further digital signal processing techniques on the primary detector signal or any secondary detector signal derived thereof, e.g. windowing, filtering, Goertzel algorithm, crosscorrelation and autocorrelation. Besides the detector signal and the information on the at least one electrically measureable quantity, in particular the forward voltage, one or a plurality of further parameters and/or items of information can influence said relationship. The relationship can be determined or determinable empirically, analytically or else semi-empirically. As an example, the relationship may comprise at least one of a model or calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the detector signals into the items of information may be used. Alternatively, at least one combined relationship for processing the detector signals is feasible. Various possibilities are conceivable and can also be combined.

As outlined above, the evaluation unit, specifically may be configured, e.g. by software programming, for determining at least one correction from the item of wavelength correction information. The term “wavelength correction information”, as used herein, is a broad term and is to be given its ordinary and customary meaning to a person of ordinary skill in the art and is not to be limited to a special or customized meaning. The term specifically may refer, without limitation, to an information that is used for correcting the wavelength information of the spectroscopic information on the object. The wavelength correction information may be or may be generated by a known feature, particularly a known emission peak of the emission spectrum of the light source. The wavelength correction information may be derived by comparing the measured wavelength of the feature, particularly the wavelength of the measured emission peak of the feature, to the known wavelength of the feature, particularly the known wavelength of the emission peak of the feature. The feature, particularly the emission peak, may be determined from a power density distribution of light generated by the light source. The light generated by the light source may be the illumination light. Alternatively or in addition, the light generated by the light source may be detection light from the object and/or light from a reference target. There may be different light that is generated by the light source. By considering the wavelength correction information, a relationship between at least one intensity information and at least one wavelength or at least one wavelength sub-range over one or more wavelengths may be corrected.

Thus, as an example, the evaluation unit may be configured for determining a spectrum from the at least one detector signal provided by the detector, such as a spectrum indicating a photometric or radiometric parameter as a function of the wavelength. This spectrum may be corrected by applying at least one correction function, e.g. a correction factor, e.g. a wavelength-dependent correction factor of the correction function, to the spectrum, thereby generating a corrected spectrum. The detector signal may, as an example, provide a signal as a function of the wavelength of the detection light, wherein, by using the correction, each functional value of the detector signal may be assigned to a corrected wavelength and/or wavelength range.

As an example, the detector signal may comprise a plurality of detector signals being at least a function of the wavelength of the detection light, and, optionally, also of time, specifically for time-dependent detector signals. This plurality of detector signals may form a spectrum, including the option of a digital or an analogue spectrum. Thus, as an example, each of the detector signals may summarize information from a predetermined spectral range being defined by a spectral resolution of the detector. The detector may comprise a plurality of photosensitive elements, each of the photosensitive elements being sensitive in a different spectral range and/or being exposed to a different part of the spectrum of the detection light. The entirety of the detector signals of the photosensitive elements may form the detector signal, or in the entirety, as an example, defines the spectral information, a part thereof, or a predecessor thereof. The spectral range of sensitivity of each of the photosensitive elements may be known and the intensity of the detection light as a function of the detection wavelength may be derived by this detector signal, by combining the data pairs of the photosensitive elements, each data pair comprising the respective signal of the photosensitive element and the wavelength of sensitivity. Particularly as a cause of aging, the spectral range of sensitivity of each of the photosensitive elements may change, e.g. narrow and/or broaden and/or shift. This may be compensated for by considering the wavelength correction information.

At least one or each of the spectral range of sensitivity of at least one or each of the photosensitive elements may be corrected by using a corresponding correction factor of the respective wavelength, wherein the correction factor, that may be determined by evaluating the wavelength correction information, may be provided by the evaluation unit.

Thus, as generally used herein, term “correction” is a broad term and is to be given its ordinary and customary meaning to a person of ordinary skill in the art and is not to be limited to a special or customized meaning. The term specifically may refer, without limitation, to a modification or the process of modifying at least one item of interest in accordance with one or more items of information indicating parameters known to have an impact on the item of interest. Thus, the measured spectrum may be corrected in such a way that the corrected spectrum corresponds to a spectrum under precisely known or standardized conditions. Thereby, the corrected spectrum may be compared to a reference spectrum that is determined under the precisely known or standardized conditions. As an example, the correction may comprise a modification of a measured spectrum comprised by the detector signal to correspond to standardized conditions. Such standardized conditions may be defined by a known feature position, particularly an emission peak position, more particularly of at least one emission band, in a power spectral density distribution over the wavelength. The term “position” may refer to a specific wavelength and/or a wavelength range. The correction may comprise assigning at least one intensity information of a specific wavelength in a measured spectrum to a different wavelength, such as a corrected wavelength, in a corrected spectrum.

Thus, step iii. may comprise a correction in which a measured spectrum derived from the detector signal may be modified to correspond to a corrected spectrum, specifically a corrected spectrum which presumably would have been obtained under predetermined standard conditions. The standardized conditions may be defined by using appropriate conditions, such as the known feature position, particularly an emission peak position. Other standard conditions, however, are also feasible.

For determining the correction factor, specifically the correction function, one or more calibration measurements may be performed. These calibration measurements may be performed on-line and/or in the field. Thus, the correction may be based on one or more calibration measurements. As an example, the calibration measurements may determine the at least one detector signal as a function of the wavelength. As outlined above, at least one condition may be determined as a standard condition. As an example, a known feature position, particularly an emission peak position, more particularly of at least one emission band, in a power spectral density distribution over the wavelength. By determining a ratio between the feature position, particularly the emission peak position, in a measured spectrum and the feature position, particularly the emission peak position, in a spectrum obtained under the standard conditions, a correction factor may be determined for each wavelength.

As further outlined above, the evaluation unit may be configured for correcting at least one wavelength and/or the wavelength scale of the spectroscopic information by assigning at least one detector signal to a corrected wavelength, by using the correction. Thus, as an example, the evaluation unit may be configured, e.g. by software programming, for directly or indirectly transforming at least one wavelength and/or wavelength range, e.g. of a spectrum derived from the at least one detector signal, into a corrected at least one wavelength and/or wavelength range, e.g. into a corrected spectrum. As an example and as further outlined above, the correction specifically may comprise multiplying the wavelength and/or wavelength range assigned to at least one detector signal or a portion thereof to a different wavelength and/or wavelength range. Thereby, a correction of the spectrum may be performed which takes into account the wavelength correction information. The evaluation unit specifically may be configured for using the corrected wavelength information for deriving the spectroscopic information.

As an example, the detector may be configured for generating detector signals for at least one spectral range, specifically for at least two differing spectral ranges of the light from the object, specifically at least one of sequentially and simultaneously. For example, the detector, as outlined above, may comprise an array of photosensitive elements, wherein each photosensitive element may be sensitive in a different spectral range and/or may be exposed to light in a different spectral range. The evaluation unit may be configured for individually correcting the wavelength and/or wavelength range assigned to the detector signals in differing spectral ranges and for combining the individually-corrected assignment for deriving the spectroscopic information. Thereby, individual detector signals being assigned to corrected individual wavelengths may be combined e.g. for generating a corrected spectrum.

Thus, generally, the detector may comprise an array of photosensitive elements, wherein each of the photosensitive elements may be configured for generating at least one detector signal for a specific wavelength or wavelength range. The evaluation unit may generally be configured for individually correcting each of the specific wavelength or wavelength range assigned to detector signals and for combining the detector signals for deriving the spectroscopic information. Thus, specifically in case each of the photosensitive elements is sensitive in a different spectral range and/or is exposed to light in a different spectral range, e.g. by one or more appropriate filters in a beam path of the detection light, the impact of the wavelength correction information as a correction parameter may be considered individually for each of the photosensitive elements.

As outlined above, the photosensitive elements may be sensitive to differing spectral ranges of the light from the object. The differing spectral sensitivity may be implemented by using photosensitive elements having inherently differing spectral sensitivities, such as by using differing integrated filters and/or differing sensitive materials, such as semiconductor materials. Additionally or alternatively, the differing spectral sensitivity may be achieved by using one or more wavelength-selective elements in one or more beam paths of the detection light, such as one or more of a filter, a grating, a prism or the like, configured to allow forward differing spectral portions of the detection light from the object to reach the individual photosensitive elements, sequentially or simultaneously.

The light-emitting diode may have a primary emission range at least partially located in the spectral range of 420 nm to 460 nm, more specifically in the range of 440 nm to 455 nm, more specifically at 440 nm. The luminescent material may be phosphor. The illumination light may have a spectral range at least partially located in the near-infrared spectral range, specifically in the spectral range from 1 to 3 μm, preferably from 1.3 to 2.5 μm, more preferably from 1.5 to 2.2 μm.

The detector may be configured for generating detector signals for at least two differing spectral ranges of the light from the object, specifically at least one of sequentially and simultaneously for deriving the spectroscopic information. The detector may comprise an array of photosensitive elements, wherein each of the photosensitive elements is configured for generating at least one detector signal for deriving the spectroscopic information. The spectrometer device may be configured such that the photosensitive elements are sensitive to differing spectral ranges of the light from the object. The spectrometer device may comprise at least one filter element arranged in a beam path of the light from the object, wherein the filter element may be configured such that each of the photosensitive elements is exposed to an individual spectral range of the light from the object.

The spectrometer device may further comprise at least one wavelength-selective element, the wavelength-selective element may comprise at least one of a wavelength-selective element disposed in a beam path of the illumination light and a wavelength-selective element disposed in a beam path of the detection light. The wavelength-selective element may be selected from the group of a tunable wavelength-selective element and a wavelength-selective element having a fixed transmission spectrum.

Thus, generally, the spectrometer device may further comprise at least one wavelength-selective element. As used herein, the term “wavelength-selective element” is a broad term and is to be given its ordinary and customary meaning to a person of ordinary skill in the art and is not to be limited to a special or customized meaning. The term specifically may refer, without limitation, to an arbitrary optical element which interacts with differing spectral portions of incident light in a different manner, e.g. by having at least one wavelength-dependent optical property, such as at least one wavelength-dependent optical property selected from the list consisting of a degree of reflection, a direction of reflection, a degree of refraction, a direction of refraction, an absorption, a transmission, an index of refraction.

Therein, the wavelength selection by the at least one wavelength-selective element may take place in the at least one beam path of the illumination light, thereby selecting and/or modifying a wavelength of the illumination of the object, and/or in the detection beam path of the detection light, thereby selecting and/or modifying a wavelength of detection, e.g. for the detector in general and/or for each of the photosensitive elements. Thus, as an example, the at least one wavelength-selective element may comprise at least one of a wavelength-selective element disposed in a beam path of the illumination light and a wavelength-selective element disposed in a beam path of the detection light.

The wavelength-selective element, specifically may be selected from the group of a tunable wavelength-selective element and a wavelength-selective element having a fixed transmission spectrum. By using a tunable wavelength selective element, as an example, differing wavelength ranges may be selected sequentially, whereas, by using a wavelength-selective element having a fixed transmission spectrum, the selection of the wavelength ranges may be fixed and may, however, be dependent e.g. on a detection position, thereby allowing, as an example, in the detection light beam path, for simultaneously exposing different detectors and/or different photosensitive elements of the detector to differing spectral ranges of light.

Thus, as outlined above and as an example, the at least one wavelength-selective element may comprise at least one of a filter, a grating, a prism, a plasmonic filter, a diffractive optical element and a metamaterial. More specifically, the spectrometer device may comprise at least one filter element disposed in a beam path of the light from the object, i.e. in the beam path of the detection light, wherein the filter element, specifically may be configured such that each of the photosensitive elements is exposed to an individual spectral range of the light from the object. As an example, a variable filter element may be used, the transmission of which depends on a position on the filter element, such that, when the variable filter element is placed on top of the array of photosensitive elements, the individual photosensitive elements are exposed to differing spectral ranges of the incident light, specifically the detection light from the object. Additionally or alternatively the at least one wavelength-selective element may comprise at least one of the following elements: an array of individual bandpass filters, an array of patterned filters, an MEMS-Interferometer, an MEMS-Fabry Perot interferometer. Further elements are feasible.

The evaluation unit may be configured for determining the wavelength correction information by considering an emission spectrum of the at least one light source. The term “emission spectrum of the at least one light source”, also occasionally referred to as“central wavelength” is a broad term and is to be given its ordinary and customary meaning to a person of ordinary skill in the art and is not to be limited to a special or customized meaning. The term specifically may refer, without limitation, to a spectrum influenced by the illumination light, specifically a spectrum of light generated by the illumination light, particularly by interacting with an object and/or a reference target. Alternatively or in addition, to a spectrum of the illumination light.

The evaluation unit is configured for determining the wavelength correction information by using an emission peak position of at least one emission band in a power spectral density distribution over the wavelength of the light generated by the light source. The emission band is a characteristic, particular only and/or exclusively, of the secondary light generated by the material of the phosphor. The term “emission peak position”, also occasionally referred to as “central wavelength” is a broad term and is to be given its ordinary and customary meaning to a person of ordinary skill in the art and is not to be limited to a special or customized meaning. The term specifically may refer, without limitation, to a frequency and/or wavelength at which a respective feature shows the highest power spectral density. The light generated by the light source may be the illumination light or further light, such as the detection light or the light from the reference target, that is generated by the illumination light. For generating the detection light, the illumination light may interact with the object in a manner that detection light from the object may be radiated from the object. For generating the light from the reference target, the illumination light may interact with the reference target in a manner that light from the object may be radiated from the reference target. The further light may comprise information on the illumination light, particularly a feature position and/or an emission peak position, may be derivable by evaluating spectral information provided by the further light. The “emission band” may be a characteristic of the light-conversion, in which the “primary light” generated by the primary light source such as the at least one light-emitting diode may subsequently be transformed into “secondary light” by the one or more phosphor materials.

The emission peak position of the at least one emission band in the power spectral density distribution over the wavelength of the light that is used for determining the wavelength correction information may be used for calibrating the wavelength of the spectroscopic information. The term “calibrating the wavelength of the spectroscopic information” is a broad term and is to be given its ordinary and customary meaning to a person of ordinary skill in the art and is not to be limited to a special or customized meaning. The term specifically may refer, without limitation, to using the wavelength correction information when deriving the spectroscopic information on the object at least one time, whereby the corrected spectroscopic information then compares to spectroscopic information as derived under standardized conditions. The wavelength correction information may be used for correcting the wavelength information of the spectroscopic information on the object. Thereby, an intensity derived from the at least one detector signal generated by the detection light may be assigned to a corrected wavelength or a corrected wavelength range. Therefore, at least one wavelength or at least one wavelength range that is assigned to at least a portion of the at least one detector signal, such as a detector signal generated by a specific detector or a specific radiation sensitive component of a detector, particularly a specific photosensitive element, may be corrected by using the wavelength correction information. Specifically, at least one wavelength or at least one wavelength range that is assigned to a detector or a photosensitive element of the detector may be assigned to at least one corrected wavelength or at least one corrected wavelength range by considering the wavelength correction information.

The emission peak position of the at least one emission band in the power spectral density distribution over the wavelength of the light that is used for determining the wavelength correction information may be independent of a temperature of the light source. The term “independent of a temperature of the light source” is a broad term and is to be given its ordinary and customary meaning to a person of ordinary skill in the art and is not to be limited to a special or customized meaning. The term specifically may refer, without limitation, to the wavelength of the emission peak position moving for a maximum of 0.1%/K, preferably 0.01%/K, more preferably 0.001%/K in a temperature range from −20° C. to 85° C., preferably from −5° C. to 80° C., more preferably from 0° C. to 75° C.

The at least one evaluation unit may be configured for determining the wavelength correction information on-line in the field. The term “on-line”, as used herein, is a broad term and is to be given its ordinary and customary meaning to a person of ordinary skill in the art and is not to be limited to a special or customized meaning. The term specifically may refer, without limitation, to the property of a process of being performed in the course of another process, such as during the other process, preferably without the necessity of being separately started or initiated by a user. Thus, specifically, determining the correction from the at least one wavelength by considering the wavelength correction information may be performed as an on-line calibration without the necessity of performing a calibration using an external setup. Further, specifically, the correction of the detector signal, by using the at least one wavelength correction information may be performed during obtaining spectroscopic information on at least one object.

The at least one detector may be configured for generating the at least one detector signal by detecting at least one of:
illumination light from the light source,
detection light from the object; or
light from at least one reference target;
   wherein the evaluation unit may be configured for determining the wavelength correction information, particularly determined from the emission peak position of the at least one emission band in the power spectral density distribution over the wavelength, of the respective detected light. The detected illumination light may, particularly thus, have a spectrum that is free of an influence by the object and/or the reference target. The term “light from the at least one reference target” as used herein is a broad term and is to be given its ordinary and customary meaning to a person of ordinary skill in the art and is not to be limited to a special or customized meaning. The term specifically may refer, without limitation, to light propagating from the reference target to the spectrometer device or more specifically to the detector of the spectrometer device, e.g. diffusely reflected light. The detection light may comprise at least one of illumination light reflected by the reference target, illumination light scattered by the reference target, illumination light transmitted by the reference target, luminescence light generated by the reference target, e.g. phosphorescence or fluorescence light generated by the reference target after optical, electrical or acoustic excitation of the reference target by the illumination light or the like. The reference target may have a known influence on the spectrum of the illumination light. The reference target comprise a material with known optical impact on the detected light from the reference target. Such a material may be Barium Sulfate or the like. There may be further materials.

The at least one detector signal evaluated for deriving the spectroscopic information on the object may comprise the wavelength correction information. The emission peak position of the at least one emission band in the power spectral density distribution over the wavelength of the respective detected light may be detected by the at least one detector prior to deriving the spectroscopic information on the object.

The spectrometer device may be further comprising at least one measurement unit for generating at least one item of information on at least one electrically measurable quantity, particularly a forward voltage, required for driving the light-emitting diode, and the evaluation unit may be further configured for taking into consideration the item of information on the at least one electrically measureable quantity when deriving the spectroscopic information from the detector signal. Thereby, at least one intensity of the spectroscopic information may be corrected

The term “measurement unit” as used herein is a broad term and is to be given its ordinary and customary meaning to a person of ordinary skill in the art and is not to be limited to a special or customized meaning. The term specifically may refer, without limitation, to an arbitrary device or a combination of devices configured for measuring one or more electrical parameters of an electrical power provided to the light source, specifically to the at least one light-emitting diode, and generating at least one item of information on the electrically measurable quantity, in particular the forward voltage. The measurement unit may be an element of the driving unit and/or the evaluation unit.

The term “electrically measurable quantity” as used herein is a broad term and is to be given its ordinary and customary meaning to a person of ordinary skill in the art and is not to be limited to a special or customized meaning. The term specifically may refer, without limitation, to any parameter required for driving the light-emitting diode which is electrically measurable. For example, the electrically measurable quantity may be at least one quantity selected from the group consisting of: a forward voltage; a fed in electrical power; a current; resistance, inductance, capacitance and the like.

The term “forward voltage” as used herein is a broad term and is to be given its ordinary and customary meaning to a person of ordinary skill in the art and is not to be limited to a special or customized meaning. The term specifically may refer, without limitation, to a voltage to be applied to the LED in the forward direction, i.e. as with a positive contact of a voltage or current source applied to a p-layer of the LED and a negative contact applied to the n-layer of the LED, in order to generate a predetermined electrical current through the LED. As an example, the predetermined current defining the forward voltage may be a current which is known to generate a predetermined light output of the light source and/or of the light-emitting diode. The predetermined current specifically may be in the range of 10 mA to 500 mA, more specifically in the range of 100 mA to 300 mA. Additionally or alternatively, the term “forward voltage” may refer to a minimum voltage to be applied to the LED in the forward direction in order to generate a significant electrical current, specifically a predetermined electrical current defined to be a minimum electrical current, through the LED, e.g. an electrical current amounting a minimum threshold and/or above a minimum threshold. The forward voltage, as an example, may be a voltage, which may be derived from a diode characteristic of the LED, i.e. from a graph indicating the electrical current as a function of the voltage applied to the LED. The forward voltage, as an example, may be derived by a logarithmic plot of the diode characteristic of the LED, e.g. by determining a kink in the forward branch of the characteristic and/or by determining the voltage at an intersection of a straight line characterizing the steep portion of the forward branch with the horizontal axis or voltage axis. Thus, the forward voltage generally may denote the voltage to be applied to the LED in forward direction (p to n) to drive an electrical current through the diode. The forward voltage may depend on a bandgap of the LED. Thus, generally, an LED, having a primary emission wavelength or primary emission wavelength range, in a short wavelength range, such as in the blue spectral range, may generally require a higher forward voltage than an LED emitting light in a longer wavelength range, such as red light. The forward voltage sometimes also is referred to as a “forward bias” or as a “junction voltage”. For the forward voltage, the symbols V_{F} or V_{LED} may be used.

Thus, generally, a direction of the electrical current through the LED in which the current flows from a p-doped layer of the LED into an n-doped layer, and/or a direction of the electrical current, in which a p-side or p-doped layer of the LED is connected to a positive connector of an electrical power source and in which an n-side or n-doped layer of the LED is connected to a negative connector of the electrical power source, may be determined to be a “forward direction”.

For generating the at least one item of information on the at least one electrically measureable quantity, in particular the forward voltage, required for driving the light-emitting diode, e.g. for driving the LED with a predetermined electrical current in the forward direction, the measurement unit, e.g. as part of the driving unit, may comprise one or more measurement devices or measurement elements, such as one or more voltage measurement devices. The at least one item of information on the at least one electrically measureable quantity, in particular the forward voltage, as an example, may be provided by the measurement unit in the form of at least one electrical signal and/or electrical information, e.g., comprising one or both of an analogue signal and a digital signal. The electrical signal comprising the at least one item of information on the at least one electrically measureable quantity, in particular the forward voltage, may directly or indirectly be provided to the evaluation unit. The electrical signal may be time-dependent or static.

In a further aspect, a method for calibrating a spectrometer device for obtaining spectroscopic information on at least one object is disclosed. The method comprises the following steps that may be performed in the given order. However, a different order may also be possible. In particular, one, more than one or even all of the method steps may be performed once or repeatedly.

Further, the method steps may be performed successively or, alternatively, one or more of the method steps may be performed in a timely overlapping fashion or even in a parallel fashion and/or in a combined fashion. The method may further comprise additional method steps that are not listed.

The method comprises the following steps:
a. electrically driving at least one light source by using at least one driving unit (138), the light source comprising at least one light-emitting diode and at least one luminescent material for light-conversion of primary light generated by the light-emitting diode;
b. detecting light by using at least one detector and, thereby, generating at least one detector signal; and
c. evaluating the at least one detector signal generated by the detector by using at least one evaluation unit, and determining wavelength correction information by using, particularly a feature position, particularly an emission peak position of at least one emission band in, a power spectral density distribution over the wavelength of the light generated by the light source, and determining the wavelength correction information by using an emission peak position of at least one emission band in a power spectral density distribution over the wavelength of the light generated by the light source, wherein the luminescent material is phosphor, wherein the emission band is a characteristic of the secondary light generated by the material of the phosphor.

The emission peak position of the at least one emission band in the power spectral density distribution over the wavelength of the light, particularly detect by the at least one detector, may be independent of a temperature of the light source. The power spectral density distribution over the wavelength of the detected light may be determined by using the at least one detector.

In a further aspect, a method of obtaining spectroscopic information on at least one object is disclosed. The method comprises the following steps that may be performed in the given order. However, a different order may also be possible. In particular, one, more than one or even all of the method steps may be performed once or repeatedly. Further, the method steps may be performed successively or, alternatively, one or more of the method steps may be performed in a timely overlapping fashion or even in a parallel fashion and/or in a combined fashion. The method may further comprise additional method steps that are not listed.

The method comprises the following steps:
1. electrically driving at least one light source by using at least one driving unit, the light source comprising at least one light-emitting diode and at least one luminescent material for light-conversion of primary light generated by the light-emitting diode;
2. illuminating the object with illumination light generated by the light source;
3. detecting light, by using at least one detector, and, thereby, generating at least one detector signal; and
4. evaluating at the least one detector signal by using at least one evaluation unit, and deriving the spectroscopic information on the object from the at least one detector signal by using the evaluation unit, wherein the spectroscopic information on the object is derived by taking into consideration wavelength correction information, particularly derived from the at least one detector signal.

The wavelength correction information may be determined by using a method for calibrating the spectrometer device for obtaining the spectroscopic information on the at least one object. The method may further comprise a step of generating, by using at least one measurement unit, at least one item of information on at least one electrically measureable quantity required for driving the light-emitting diode; wherein the item of information on the at least one electrically measureable quantity, in particular a forward voltage, may be taken into consideration when deriving the spectroscopic information from the detector signal. Any one of the methods described above, specifically, may be performed on-line in the field.

As further outlined above, any one of the methods described above and/or according to any one of the embodiments described in further detail below, may fully or partially be at least one of computer-controlled, computer-implemented, and computer-assisted, e.g. by using one or more computer programs running on at least one processor, e.g., at least one processor of the spectrometer device, e.g. of at least one processor integrated within the detector and/or within the evaluation unit. Specifically, as outlined above, at least a step of any one of the methods that is involving the use of the evaluation unit may be at least one of computer-controlled, computer-implemented, and computer-assisted. It shall be noted, however, that other steps of the method may also fully or partially be at least one of computer-controlled, computer-implemented, and computer-assisted, such as one or more of steps a., b., and c. of the method for calibrating a spectrometer device for obtaining spectroscopic information on at least one object and/or one or more of steps 1., 2., 3., and 4. of the method of obtaining spectroscopic information on at least one object.

In a further aspect, a computer program is disclosed. The computer program is comprising instructions which, when the instructions are executed by the evaluation unit of the spectrometer device, cause the evaluation unit to perform any method described elsewhere herein. In a further aspect, a non-transient computer-readable storage medium is disclosed. The is non-transient computer-readable storage medium comprising instructions which, when the instructions are executed by the evaluation unit of the spectrometer device, cause the evaluation unit to perform any method described elsewhere herein.

As used herein, the terms “computer-readable data carrier”, “computer-readable storage medium” and “non-transient computer-readable medium” are broad term and are to be given their ordinary and customary meaning to a person of ordinary skill in the art and are not to be limited to a special or customized meaning. The terms specifically may refer, without limitation, to data storage means, specifically non-transitory data storage means, such as a hardware storage medium having stored thereon computer-executable instructions. The computer-readable data carrier or storage medium or computer-readable medium specifically may be or may comprise a storage medium such as a random-access memory (RAM) and/or a read-only memory (ROM).

As used herein, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically are used only once when introducing the respective feature or element. In most cases, when referring to the respective feature or element, the expressions “at least one” or “one or more” are not repeated, notwithstanding the fact that the respective feature or element may be present once or more than once.

Further, as used herein, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restrictions regarding the scope of the invention and without any restriction regarding the possibility of combining the features introduced in such way with other optional or non-optional features of the invention.

The spectrometer device and the methods according to the present invention, in one or more of the above-mentioned embodiments and/or in one or more of the embodiments described in further detail below, provide a large number of advantages over known devices and methods of similar kind. Specifically, an on-line correction or calibration may be performed. More specifically, the wavelength correction information may provide a reliable correction parameter, which typically changes with an aging of at least some components of the spectrometer device, for deriving the spectrum or the spectral information on the object thereof.

Although the spectrum of the light source, and particularly the light emitting diode, may be temperature dependent, the position of the emission bands of the light source may be stable over a large temperature range. Therefore, the light source may be an ideal reference for deriving the wavelength correction information that is provided by the spectrometer device itself. Each time, a reference measurement by using the spectrometer device may be applied, the spectrometer device may be recalibrated by using the wavelength correction information. Thereby, the wavelength information comprised by the spectroscopic information on the object may be correct. The wavelength correction information may be determined independent from the temperature of the light source that may not affect the calibration.

Further, the use of phosphor LEDs instead of or in addition to conventional thermal emitters such as incandescent lamps with a tungsten wire as a light source, may provide for several advantages. Thus, in general, even though thermal emitters may provide for a flat spectrum, low temperature dependency and a high power spectral density even at long wavelengths, such as in the NIR range, thermal emitters typically are not well-suited for large-volume spectrometer production. Thus, typically, a high complexity of the manufacturing process, a low conversion efficiency from electrical to optical power and physical limitations in miniaturization are to be noted as disadvantages for thermal emitters. By using LEDs, specifically phosphor LEDs, these disadvantages may be overcome. LEDs have proven to be reliable light sources, such as standardized light sources in the visible light regime.

In the context of the present invention, broadband light sources may be provided by using one or more phosphor LEDs in the spectrometer device, comprising the at least one light-emitting diode and the at least one luminescent material or phosphor. Thereby, as an example, a white light source may be created and/or a broadband light source in the infrared range, specifically in the NIR range. The phosphor may convert photons having a shorter wavelength, and, thus, a higher energy, into photons having a longer wavelength or lower energy, e.g. by transferring a portion of the primary photon energy to the phosphor material, such as to the phosphor lattice. The remaining lower energy may lead to an emission of a long-wavelength photon.

Consequently, the luminescent material may be configured for absorbing one or more primary photons generated by the light-emitting diode and may, in reaction to this absorption, emit one or more secondary photons. The emission of the secondary photons may take place instantaneously or after a delay or decay time. Thus, as outlined above, the luminescent material may be or may comprise at least one of a phosphorescent and a fluorescent material. The phosphorescence may lead to the effect that after turning off the primary light, such as the short-wavelength or high energy pump light, the luminescent material may emit the secondary light, such as the long wavelength light, for a characteristic life time T (tau), e.g., due to a forbidden quantum-optical transition or forbidden dipole transition. Thus, specifically, in the luminescent material, the emission of the secondary light may take place over a forbidden transition, such as a forbidden dipole transition, having a longer lifetime than e.g. spontaneous dipole allowed transition, as may be the case in many fluorescent materials.

Specifically, as outlined above, a luminescent material may be used, specifically a phosphorescent material, having an absorption in the blue spectral range and an emission in the infrared spectral range. As an example, luminescent materials may be used capable of converting blue primary light or pump light, having a wavelength of e.g. 440 nm, into near-infrared secondary light, e.g. secondary light having a wavelength in the range of 1 to 3 μm, preferably from 1.3 to 2.5 μm, more preferably from 1.5 to 2.2 μm. Additionally or alternatively, the primary light or pump light may generated by an infrared LED with a wavelength in the range from 850 nm to 940 nm, which may then be converted by the luminescent material into near-infrared secondary light having a wavelength in the range of 1 to 3 μm, preferably from 1.3 to 2.5 μm, more preferably from 1.5 to 2.2 μm.

The phosphor LED, comprising the at least one light-emitting diode and the at least one luminescent material, may be embodied as a single element. Thus, on a technical level, the phosphor LED may comprise multiple sub-components.

First of all, the phosphor LED may comprise one or more functional components, such as the LED die comprising at least one junction between at least two semiconductor regions, such as at least one p-n-transition. In the LED die, the primary light may be generated, such as the short-wavelength pump light, e.g. in the blue spectral range.

Further, the phosphor LED may comprise the at least one luminescent material, specifically the at least one phosphorescent material, which may, specifically, be placed directly on top of the LED die and which may convert the primary light, specifically the pump light, into the secondary light, specifically into the long-wavelength near-infrared light.

Further, the phosphor LED may comprise one or more substrates, specifically one or more electrically insulating substrates. Thus, as an example, the phosphor LED may comprise one or more ceramic substrates. The at least one substrate may be configured for holding the at least one LED die and the at least one luminescent material. Further, the at least one substrate may hold or comprise one or more components of electrical connectivity, such as one or more contact pads and/or one or more electrical leads, such as one or more metallic contacts and/or one or more metallic leads. Furthermore, the substrate, such as the ceramic substrate, may be configured to serve as a heat sink. Heat may be generated both in the LED die and in the luminescent material, such as due to a limited conversion of electrical energy into photonic energy, as well as in the luminescent material, e.g. during the conversion process. Said heat may be dissipated in the substrate, such as in ceramic substrate.

The spectrometer device using the at least one LED may be configured for applying a continuous wave (CW) mode and/or, preferably, at least one modulation driving scheme for improving precision and reliability of the measurement. Thus, for example, the at least one driving unit may be configured for applying a modulation driving scheme to the LED, and the evaluation device may be configured for taking into account the modulation driving scheme for deriving the at least one spectroscopic information from the at least one detector signal. As an example, LockIn-techniques, filter techniques, and the like may be applied, as known to the skilled person.

Thus, the spectrometer device may be configured for applying a modulation driving scheme to the LED for compensating for DC background of the detector and/or in order to reduce the detector noise. Thus, as an example, a band pass filter may be applied to the detector signal, in order to eliminate DC components.

The illumination light generated by the light source, specifically the phosphor LED, may be directed to illuminate the sample. For directing the illumination light, as an example, one or more mirrors, may optionally be used. The detection light from the object, e.g. reflected light, may be directed to the detector, wherein, optionally, one or more optical components may be used. As an example, one or more wavelength-selective elements may be used, such as one or more dispersive elements, e.g. for splitting the detection light into its spectral components.

By the detector, one or more detector signals may be recorded, e.g. by using a readout electronics, comprised by the spectrometer device, specifically by one or both of the detector and the evaluation device. The readout electronics, as an example, may comprise one or more signal processing devices. Thus, as outlined above, for evaluation by the evaluation device, the “raw” detector signal may be used, and/or one or more secondary detector signals derived thereof, such as one or more filtered detector signals. Further, the at least one detector signal, primary or secondary, may also be combined with further information, such as information on a wavelength, e.g. derived from a number of the photosensitive element of an array of photosensitive elements from which the detector signal is derived, which is known to be exposed to a specific wavelength of a wavelength range. In the context of the present invention, specifically in the context of the evaluation of the detector signal by the evaluation unit, the option of evaluating the raw detector signal, and/or the option of evaluating a secondary detector signal, such as a preprocessed detector signal, a processed detector signal, or a combined detector signal, is feasible. Still, however, the invention specifically is interesting for correcting the “raw” detector signal, specifically a detector signal, indicating a signal intensity as a function of the detection wavelength. Other options, however, are also feasible.

As an example, the detector signal, e.g. by the detector itself and/or by the evaluation unit, may be processed or preprocessed into a secondary detector signal, by applying one or more Fourier transformations. As an example, a Fast Fourier Transformation may be applied. From the processed, secondary detector signal, the at least one spectroscopic information may be derived, such as by a software being executed by the evaluation unit. Thus, as an example, the Fourier transform of the detector signal may be read out by the software of the spectroscopic device, specifically of the evaluation device, and post-processed into the spectroscopic information on the object.

LEDs and phosphor LEDs, as outlined above, may, thus, provide for an efficient light source which may be modulated in order to perform specific evaluation schemes and in order to reduce noise and artifacts. By further using the at least one item of information on the electrically measureable quantity, in particular the forward voltage, as a correction or calibration parameter, temperature variations within the light source, specifically within the LED, may fully or partially be compensated for. Thus, for typical LEDs, as used herein, when operating with the maximum voltage and current that the LED can withstand, the temperatures of the various components of the light source, specifically of the LED, may vary over a large temperature range. As an example, standard operation currents may range from 2 mA to 1000 mA, typically from 10 mA to 300 mA. As an example, forward voltages may be in the range from 1.5 V to 3.5 V, typically from 2.25 V to 3 V. Thus, as an example, under maximum operating conditions, the emitter junction temperature may be 135° C. The operating case temperature may vary from −40° C. to 135° C. and the emitter storage temperature may vary from −40° C. to 125° C. The ESD sensitivity of the LED may be 250 V under the standard ANSI/ESDA/JEDEC JS-001-2012. These typical parameters show the large range of temperature variation, which may have an impact on spectroscopic information on the object derived by the spectrometer device. It shall be noted that other parameters and other parameter ranges are feasible, too.

It is generally known that, with different compositions of the luminescent material, such as different compositions of phosphors, the phosphor LEDs generate different spectra. Typically, each phosphor LED has multiple peaks in the spectrum, wherein the spectrum typically is spread over a wide wavelength range. However, even giving the same current to the phosphor LED, the spectral properties or the spectrum may change with temperature. These changes may include shifts of the emission peaks, broadening or narrowing of the spectrum, increases or decreases of the emission and the like. In many cases, however, the emission at some wavelengths is affected to a larger extent than the emission at other wavelengths. Thus, typically, within the spectrum, there is a specific central wavelength, where the power, specifically the power spectral density, typically does not change with temperature. Each wavelength therefore typically has its own temperature coefficient, regarding to the increment/decrement of the power. Therefore, the shape of the spectrum changes with temperature. By using the electrically measureable quantity, in particular the forward voltage, as a correction parameter, an individual temperature correction of the spectrum at the different wavelengths may be performed. Thus, as outlined above, the evaluation unit may be configured for individually correcting the detector signals in differing spectral ranges and for combining the individually-corrected detector signals for deriving the spectroscopic information. More specifically, as also outlined above, this individual correction may be performed by using an array of photosensitive elements, wherein each of the photosensitive elements may be configured for generating at least one detector signal and wherein each of the detector signals may individually be corrected by using the electrically measureable quantity, in particular the forward voltage, as a correction parameter. Finally, the corrected detector signals may be combined for deriving the spectroscopic information.

By using the electrically measureable quantity, in particular the forward voltage, as a correction parameter, temperature changes as well as individual properties of the phosphor LEDs may be corrected for. Thus, as an example, when applying the same current to the LED, the forward voltage of the LED typically decreases while temperature increases. Each type of the LED has its own characteristic forward voltage to temperature curve. Typically, the forward voltage of the LED linearly decreases with rising temperature, such as with a slope in the range of 1·10⁻⁴ to 1·10⁻³ V/K.

Further, the spectrometer device and the method may take into account the characteristics of the luminescent materials used in the light source. Thus, as outlined above, typically, a delay occurs between the absorption of the at least one primary photon by the luminescent material and the emission of the at least one secondary photon by the luminescent material. This delay may be characterized by the so-called “characteristic time constant” τ, also referred to as the “time constant”, the “decay time” or the “saturation time”. As generally known to the skilled person, the term “time constant”, as used herein, is a broad term and is to be given its ordinary and customary meaning to a person of ordinary skill in the art and is not to be limited to a special or customized meaning. When used in the context of processes in which a rate or probability of a process, such as emission of a photon, is proportional to the population of one or more states or process states, the population typically changes exponentially. The time constant τ, in these processes, may determine the 1/e-time of the process. For the luminescent material or converter, specifically for the phosphor, two different time constants may occur. Firstly, a first time constant may describe the typical time for reaching a saturation of the emission of converted light. Secondly, a second time constant may describe the typical time of an afterglow of the luminescent material or converter.

Typical time constants of phosphor converters are in the range of 0.1 ms to <10 ms. The time constants typically differ between different phosphor LEDs and/or between different types of the luminescent material or phosphor. Typically, shorted wavelengths emitting phosphor exhibit smaller time constants. Additionally, decay τ_{d} and growth constant τ_{g} may depend on the wavelength. The time constants typically are extracted from step response of the optical signal by applying/shutting off the forward current.

After turning off the forward current, the signal or emission typically decays according to equation (1):

$$S ( t ) = {S}_{max} {e}^{- ( t - {t}_{0} ) / {τ}_{d}} + {S}_{0} \qquad ( 1 )$$

After turning on the forward current, the signal or emission typically grows according to equation (2):

$$S ( t ) = {S}_{max} ( 1 - {e}^{- ( t - {t}_{0} ) / {τ}_{g}} ) + {S}_{0} \qquad ( 2 )$$

For both equations (1) and (2), S₀ is the optical signal level at t₀, when the forward current is applied/shut off. Sₘₐₓ is the reached optical signal level as t 5.

A further characteristic of the LED is the light output power as a function of the forward current. Thus, generally, by increasing the input current, the power admitted by the LED is increased. The shape, e.g. the slope, of the curve of the light output as a function of the forward current is characteristic to the individual LED.

As outlined above, using the electrically measureable quantity, in particular the forward voltage, as a control or correction parameter for spectroscopic purposes, an efficient and reliable on-line correction or on-line calibration is feasible. Thereby, various challenges of typical spectrometers and their respective calibration may be overcome. Specifically, in typical spectroscopic processes, reference measurements with the spectrometer allow for calibrating instrument response, so the measurement provides information on the sample only. If, however, an optical component of the spectrometer device changes between the reference measurement and the sample measurement, the sample information is affected by the system change, so the information on the sample may be falsified. In particular, when the optical spectrum S_{Ls}(λ) of the light source changes between the reference measurement, during which the light source has an optical spectrum S_{LS,Ref}(λ), and the actual sample measurement, during which the light source has an optical spectrum S_{LS,Sample}(λ), the spectroscopic information on the object or sample is falsified, since the spectrum typically deviates by the ratio of both spectra S_{LS}(λ), S_{LS,Sample}(λ).

In phosphor LEDs, the situation is typically even more complex, since the spectrum of the phosphor LED is a combination of the spectrum of the LED and the luminescent material. Both components of the phosphor LED may be affected by temperature changes in a different way. Thus, for phosphor LEDs, the spectrum typically may be described by equation (3):

$${S}_{Ls} ( λ , {T}_{pn} , {T}_{p} ) = {S}_{blue} ( λ , {T}_{pn} ) \cdot {S}_{phosphor} ( λ , {T}_{p} ) \qquad ( 3 )$$

Therein, S_{LS}(λ, Tₚₙ, Tₚ) denotes the spectrum of the light source LS as a function of the wavelength λ, the p-n-junction temperature of the LED Tₚₙ, and the temperature of the phosphor Tₚ. S_{blue}(λ, Tₚₙ) denotes the spectrum of the LED, e.g. the blue LED, and Sₚₕₒₛₚₕₒᵣ(λ, Tₚ) denotes the spectrum of the luminescent material, e.g. the phosphor.

Both sub-components, the LED and the luminescent material, show an individual temperature response. Thus, a system temperature change or shift or an ambient temperature change or shift, specifically between a reference measurement and a sample measurement, typically affects the spectrum by affecting both the LED junction and the luminescent material.

The at least one item of information on the electrically measureable quantity, in particular the forward voltage, such as the forward voltage itself and/or at least one other item of information directly or indirectly derived from the forward voltage, e.g. a preprocessed value of measurement of the forward voltage, or another electrically measureable quantity required for driving the light-emitting diode, such as a fed in electrical power, a current, a resistance, an inductance, a capacitance and the like, provides for a reliable correction parameter. By taking into consideration the at least one item of information on the electrically measureable quantity, in particular the forward voltage, when deriving the spectroscopic information from the detector signal, the various temperature changes may be accounted for. Thus, a self-referencing scheme may be applied, in which an internal parameter, i.e. the item of information on the electrically measureable quantity, in particular the forward voltage, may be used for referencing, specifically on-line. This will be outlined on the following in an exemplary fashion using the forward voltage as an example for the electrically measureable quantity required for driving the light-emitting diode. Without wishing to be bound by this theory, this is due to the fact that a fixed dependency exists between the temperature of the luminescent material Tₚ and the temperature Tₚₙ of the p-n-junction of the LED:

$${T}_{p} = {T}_{p} ( {T}_{pn} ) \qquad ( 4 )$$

Further, a fixed dependency between the forward voltage U_{F} and the temperature Tₚₙ of the pn-junction exists:

$${T}_{pn} = {T}_{pn} ( {U}_{F} ) \qquad ( 5 )$$

By using these dependencies, a model may be created which takes into account the entire light source, the model merely being based on the junction temperature Tₚₙ rather than on a combination of the junction temperature and the phosphor temperature. The junction temperature Tₚₙ is a function of the forward voltage U_{F}. Thereby, the emission spectrum of the light source may be described by

$${S}_{Ls} = {S}_{Ls} ( λ , {T}_{pn} ( {U}_{F} ) , {T}_{p} ( {T}_{pn} ( {U}_{F} ) ) \qquad ( 6 )$$

The emission spectrum of the light source, thus, is a function of the wavelength and of the forward voltage. The function, as an example, may be determined empirically, semi-empirically or even theoretically. The function may be determined in one or more calibration processes, by determining the forward voltage and determining, as an example, the intensity as a function of the wavelength. Thereby, one or more calibration curves may be determined and may be taken into account in the evaluation step. Thus, by measuring the forward voltage for reference or sample measurement, or during one measurement, the influence of temperature can be efficiently corrected for.

As an example, as outlined above, the emission spectrum of the light source, before or after interaction with the object, may be described as a function of the forward voltage, as outlined in equation (6) above. For correcting the emission spectrum, as an example, the emission spectrum may be corrected to at least one reference forward voltage U_{F,Ref}. As an example, this reference forward voltage may be a forward voltage, which is expected at or which is measured at a specific reference temperature, such as at room temperature. Additionally or alternatively, the forward voltage at one or more other reference temperatures may be used, such as a housing temperature, a heat sink temperature or any other system-specific temperature.

For the correction, at least one forward voltage-dependent correction factor or correction function k(λ, U_{F}) may be used:

$${S}_{LS , corr} ( λ , {U}_{F , ref} ) = k ( λ , {U}_{F} ) \cdot {S}_{LS} ( {S}_{LS} ( λ , {U}_{F} ) ) \qquad ( 7 )$$

As indicated, the correction function k(λ, U_{F}) may be a function of the wavelength A and the forward voltage U_{F}. The correction function may be determined by one or more calibration measurements, e.g. by a factory calibration. As an example, the calibration measurements may imply, for a plurality of different wavelengths and/or for a plurality of different wavelength ranges, the respective signal as a function of the measurement forward voltage, for various forward voltages. From the empirical data, as an example, for each wavelength or wavelength range, one or more correction factors may be derived, describing the correction as a function of the forward voltage, e.g. by fitting a correction curve to the empirical data and/or by generating a model for the dependency of the signal on the forward voltage. Thus, generally, as an example, an analytical, empirical or semi-empirical model may be used for the correction. Examples will be given in further detail below.

Thus, generally, the correction, the correction factor or the correction function k(λ, U_{F}) may be determined, e.g. calculated, based on an analytical model of the dependence S_{LS,model}(λ, U_{F}). For a specific phosphor LED, the analytical model may be determined in a factory calibration process, or in-field calibration process, e.g. under controlled environment conditions, such as a known temperature. Additionally or alternatively, a batch calibration may be performed. Thus, for a batch of phosphor LEDs, a model, such as an analytical model, may be obtained from independent measurement of representative devices. This method may also be referred to as a calibration to a “gold standard”.

The calibration factor, as an example and as outlined above, may correct the spectrum to correspond to a certain reference, such as to a reference forward voltage U_{F,Ref}, e.g. a reference forward voltage measured at a reference temperature. As outlined above, from the calibration data, a model S_{LS,model}(λ, U_{F}) may be derived, e.g. by fitting a reference curve to experimental data showing the signal at a specific wavelength as a function of the measured forward voltage, e.g. for various wavelengths. The correction factor or the correction function k(λ, U_{F}) may be derived thereof, as an example, according to equation (8):

$$k ( λ , {U}_{F} ) = \frac{{S}_{LS , model} ( λ , {U}_{F , Ref} )}{{S}_{LS , model} ( λ , {U}_{F} )} \qquad ( 8 )$$

Thus, in subsequent measurements, the detector signal, e.g. for each wavelength, may be corrected by multiplying the detector signal with the correction factor or the correction function k(λ, U_{F}), thereby generating detector signals, which are widely independent on the actual temperatures at the various locations of the spectrometer device and, further, which are widely unaffected by temperature drifts and the like.

Summarizing and without excluding further possible embodiments, the following embodiments may be envisaged:
Embodiment 1: A spectrometer device for obtaining spectroscopic information on at least one object, the spectrometer device comprising:
   i. at least one light source for generating illumination light for illuminating the object, the light source comprising at least one light-emitting diode and at least one luminescent material for light-conversion of primary light generated by the light-emitting diode;
   ii. at least one detector for detecting light and, thereby, generating at least one detector signal;
   iii. at least one evaluation unit configured for deriving the spectroscopic information on the object from the at least one detector signal, wherein the evaluation unit is configured for deriving the spectroscopic information on the object by taking into consideration wavelength correction information, particularly derived from the at least one detector signal.
Embodiment 2: The spectrometer device according to the preceding Embodiment, wherein the light-emitting diode has a primary emission range at least partially located in the spectral range of 420 nm to 460 nm, more specifically in the range of 440 nm to 455 nm, more specifically at 440 nm.
Embodiment 3: The spectrometer device according to any one of the preceding Embodiments, wherein the luminescent material is phosphor.
Embodiment 4: The spectrometer device according to any one of the preceding Embodiments, wherein the illumination light has a spectral range at least partially located in the near-infrared spectral range, specifically in the spectral range from 1 to 3 μm, preferably from 1.3 to 2.5 μm, more preferably from 1.5 to 2.2 μm.
Embodiment 5: The spectrometer device according to any one of the preceding Embodiments, wherein the detector is configured for generating detector signals for at least two differing spectral ranges of the light from the object, specifically at least one of sequentially and simultaneously for deriving the spectroscopic information.
Embodiment 6: The spectrometer device according to any one of the preceding Embodiments, wherein the detector comprises an array of photosensitive elements, wherein each of the photosensitive elements is configured for generating at least one detector signal for deriving the spectroscopic information.
Embodiment 7: The spectrometer device according to any one of the preceding Embodiments, wherein the spectrometer device is configured such that the photosensitive elements are sensitive to differing spectral ranges of the light from the object.
Embodiment 8: The spectrometer device according to any one of the preceding Embodiments, wherein the spectrometer device comprises at least one filter element arranged in a beam path of the light from the object, wherein the filter element is configured such that each of the photosensitive elements is exposed to an individual spectral range of the light from the object.
Embodiment 9: The spectrometer device according to any one of the preceding Embodiments, the spectrometer device further comprising at least one wavelength-selective element, the wavelength-selective element comprising at least one of a wavelength-selective element disposed in a beam path of the illumination light and a wavelength-selective element disposed in a beam path of the detection light.
Embodiment 10: The spectrometer device according to any one of the preceding Embodiments, wherein the wavelength-selective element is selected from the group of a tunable wavelength-selective element and a wavelength-selective element having a fixed transmission spectrum.
Embodiment 11: The spectrometer device according to any one of the preceding Embodiments, wherein the evaluation unit is configured for determining the wavelength correction information by considering an emission spectrum of the at least one light source.
Embodiment 12: The spectrometer device according to any one of the preceding Embodiments, wherein the evaluation unit is configured for determining the wavelength correction information by using an emission peak position of at least one emission band in a power spectral density distribution over the wavelength of the light generated by the light source.
Embodiment 13: The spectrometer device according to any one of the preceding Embodiments, wherein the emission position of the at least one emission band in the power spectral density distribution over the wavelength of the light that is used for determining the wavelength correction information is used for calibrating the wavelength of the spectroscopic information.
Embodiment 14: The spectrometer device according to any one of the preceding Embodiments, wherein the emission peak position of the at least one emission band in the power spectral density distribution over the wavelength of the light used for determining the wavelength correction information is independent of a temperature of the light source.
Embodiment 15: The spectrometer device according to any one of the preceding Embodiments, wherein the at least one evaluation unit is configured for determining the wavelength correction information in the field.
Embodiment 16: The spectrometer device according to any one of the preceding Embodiments, wherein the at least one detector is configured for generating the at least one detector signal by detecting at least one of:
   illumination light from the light source,
   detection light from the object; or
   light from at least one reference target;
      wherein the evaluation unit is configured for determining the wavelength correction information, particularly determined from the emission peak position of the at least one emission band in the power spectral density distribution over the wavelength, of the respective detected light.
Embodiment 17: The spectrometer device according to any one of the preceding Embodiments, wherein the at least one detector signal evaluated for deriving the spectroscopic information on the object comprises the wavelength correction information.
Embodiment 18: The spectrometer device according to any one of the preceding Embodiments, wherein the emission peak 193 position of the at least one emission band in the power spectral density distribution over the wavelength of the respective detected light is detected by the at least one detector prior to deriving the spectroscopic information on the object.
Embodiment 19: The spectrometer device according to any one of the preceding Embodiments, wherein the spectrometer device is further comprising at least one measurement unit for generating at least one item of information on at least one electrically measurable quantity required for driving the light-emitting diode, wherein the evaluation unit is further configured for taking into consideration the item of information on the at least one electrically measureable quantity when deriving the spectroscopic information from the detector signal.
Embodiment 20: A method for calibrating a spectrometer device for obtaining spectroscopic information on at least one object, the method comprising:
   a. electrically driving at least one light source by using at least one driving unit, the light source comprising at least one light-emitting diode and at least one luminescent material for light-conversion of primary light generated by the light-emitting diode;
   b. detecting light by using at least one detector and, thereby, generating at least one detector signal; and
   c. evaluating the at least one detector signal generated by the detector by using at least one evaluation unit, and determining wavelength correction information by using, particularly a feature position, more particularly an emission peak position of at least one emission band in, a power spectral density distribution over the wavelength of the light generated by the light source.
Embodiment 21: The method according to the preceding Embodiment, wherein the emission peak position of the at least one emission band in the power spectral density distribution over the wavelength of the light is independent of a temperature of the light source.
Embodiment 22: The method according to any the two preceding Embodiments, wherein the power spectral density distribution over the wavelength of the detected light is determined by using the at least one detector.
Embodiment 23: A method of obtaining spectroscopic information on at least one object, the method comprising:
   1. electrically driving at least one light source by using at least one driving unit, the light source comprising at least one light-emitting diode and at least one luminescent material for light-conversion of primary light generated by the light-emitting diode;
   2. illuminating the object with illumination light generated by the light source;
   3. detecting light, by using at least one detector, and, thereby, generating at least one detector signal; and
   4. evaluating at the least one detector signal by using at least one evaluation unit, and deriving the spectroscopic information on the object from the at least one detector signal by using the evaluation unit, wherein the spectroscopic information on the object is derived by taking into consideration wavelength correction information, particularly derived from the at least one detector signal.
Embodiment 24: The method according to the preceding Embodiment, wherein the wavelength correction information is determined by using a method for calibrating the spectrometer device for obtaining the spectroscopic information on the at least one object according to any one of preceding Embodiments related to said calibration method.
Embodiment 25: The method according to any the two preceding Embodiments, the method further comprising a step of generating, by using at least one measurement unit, at least one item of information on at least one electrically measureable quantity required for driving the light-emitting diode; wherein the item of information on the at least one electrically measureable quantity, in particular a forward voltage, is taken into consideration when deriving the spectroscopic information from the detector signal.
Embodiment 26: A computer program comprising instructions which, when the instructions are executed by the evaluation unit of the spectrometer device according to any one of the preceding Embodiments referring to a spectrometer device, cause the evaluation unit to perform the method according to any one of the preceding Embodiments referring to a method.
Embodiment 27: A non-transient computer-readable storage medium comprising instructions which, when the instructions are executed by the evaluation unit of the spectrometer device according to any one of the preceding Embodiments referring to a spectrometer device, cause the evaluation unit to perform any one of the methods according to any one of the preceding Embodiments referring to a method.

### SHORT DESCRIPTION OF THE FIGURES

Further optional features and embodiments will be disclosed in more detail in the subsequent description of embodiments, preferably in conjunction with the dependent claims. Therein, the respective optional features may be realized in an isolated fashion as well as in any arbitrary feasible combination, as the skilled person will realize. The scope of the invention is not restricted by the preferred embodiments. The embodiments are schematically depicted in the Figures. Therein, identical reference numbers in these Figures refer to identical or functionally comparable elements.

In the Figures:

FIG. 1 shows a schematic overview of a spectrometer device;

FIG. 2 shows schematic cross-sectional view of a light source;

FIG. 3 shows a schematic flowchart illustrating generating and processing a detector signal;

FIG. 4 shows a diagram representing a superposition of spectra of infrared radiation of a phosphor LED at various temperatures;

FIG. 5 shows a diagram representing a change in emission power change as a function of temperature for a selected number of wavelengths;

FIG. 6 shows a diagram of a forward voltage as a function of temperature for a selected current;

FIGS. 7A and 7B show spectra of two different types of phosphor LEDs;

FIGS. 8A and 8B show diagrams representing decay constants (FIG. 8A) and growth constants (FIG. 8B) as a function of wavelength for a phosphor LED emitting between 1.3 μm and 2 μm;

FIGS. 9A and 9B show diagrams representing decay constants (FIG. 9A) and growth constants (FIG. 9B) as a function of wavelength for a phosphor LED emitting between 1.6 μm and 2.1 μm;

FIG. 10 shows a diagram representing normalized light output as a function of a forward current;

FIG. 11 shows a method for calibrating a spectrometer device;

FIG. 12 shows a method of obtaining spectroscopic information on at least one object; and

FIG. 13 shows a further exemplary spectrometer device comprising a reference target.

### DETAILED DESCRIPTION OF THE EMBODIMENTS

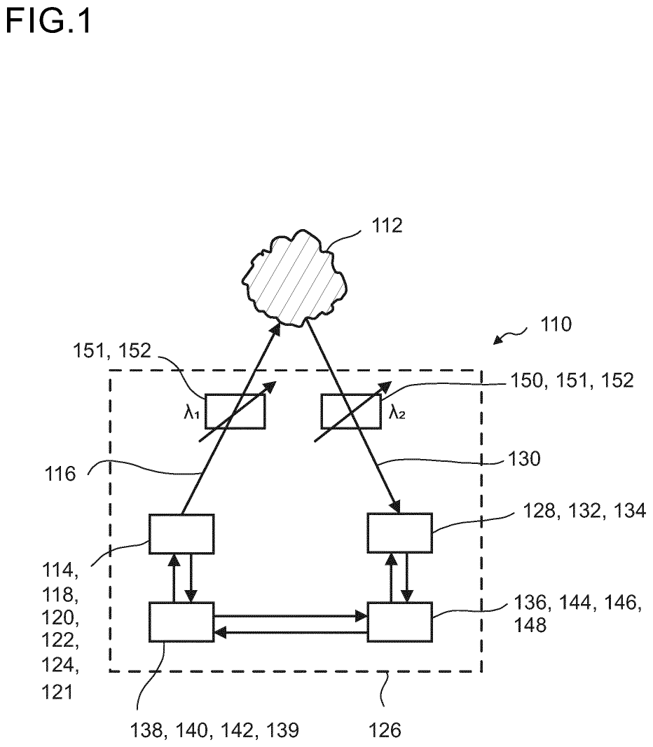

In FIG. 1, a schematic overview of a spectrometer device 110 for obtaining spectroscopic information on at least one object 112 is shown. The spectrometer device 110 may comprise a plurality of components as illustrated in FIG. 1. Possible components of the spectrometer device 110 and their interplay will be described in the following, specifically with reference to FIG. 1. The spectrometer device 110 comprises at least one light source 114 for generating illumination light 116 for illuminating the object 112. The light source 114 may be at least one of a tunable light source, a light source having at least one fixed emission wavelength and a broadband light source. The light source 114 specifically may be or may comprise at least one electrical light source. The light source 114 comprises at least one light-emitting diode 118 and at least one luminescent material 120 for light-conversion of primary light generated by the light-emitting diode 118. As an example, the light-emitting diode 118, may comprise one or more of: a light-emitting diode (LED) based on spontaneous emission of light, a light-emitting diode based on superluminescence (sLED), a laser diode (LLED).

The LED 118 may specifically comprise at least two layers of semiconductor material 121, wherein light may be generated at at least one interface between the at least two layers of semiconductor material 121, specifically due to a recombination of positive and negative electrical charges. The at least two layers of semiconductor material 121 may have differing electrical properties, such as at least one of the layers being an n-doped semiconductor material 121 and at least one of the layers being a p-doped semiconductor material 121. Thus, as an example, the LED 118 may comprise at least one pn-junction and/or at least one pin-set up. It shall be noted, however, that other device structures are feasible, too.

The light-emitting diode 118 may generate primary light, which may also be referred to as “pump light”. The primary light may subsequently be transformed into “secondary light”, such as by using light conversion, e.g. through one or more luminescent materials 120, such as phosphor materials. The at least one luminescent material 120, thus, may form at least one converter, also referred to as a light converter, transforming primary light into secondary light having different spectral properties as compared to the primary light. Specifically, a spectral width of the secondary light may be larger than a spectral width of the primary light, and/or a center of emission of the secondary light may be shifted, specifically red-shifted, compared to the primary light. Specifically, the at least one luminescent material 120 may have an absorption in the ultraviolet and/or blue spectral range and an emission in the near-infrared and/or infrared spectral range. The illumination light 116 may be or may comprise at least one of the primary light or a part thereof, the secondary light or a part thereof, or a mixture of both.

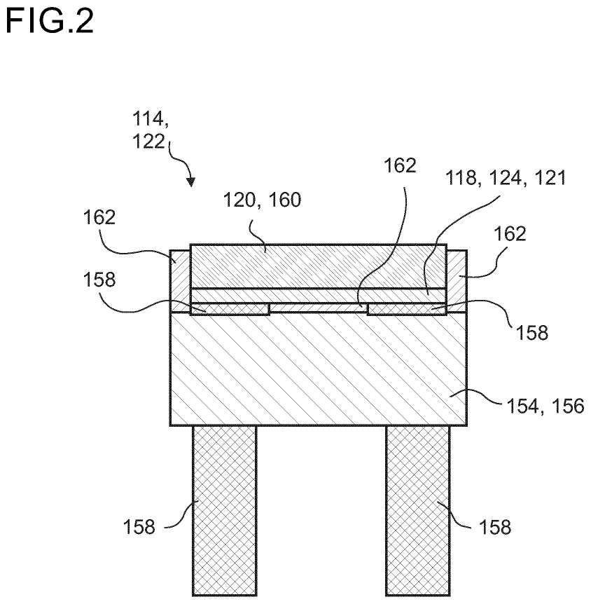

As indicated in FIG. 1, the light source 114 may specifically comprise a phosphor light-emitting diode 122, also referred to as phosphor LED 122. The phosphor LED 122 may be a combination of at least one light-emitting diode 118 configured for generating primary light or pump light, and at least one luminescent material 120, also referred to as a “phosphor”, configured for light-conversion of the primary light generated by the light-emitting diode 118. The phosphor LED 122 may form a packaged LED light source, including an LED die 124, e.g. a blue LED emitting blue pump light, as well as the phosphor, which, as an example, fully or partially coats the LED 118, which is, as an example, configured for converting the primary light or blue light into light having differing spectral properties, specifically into near-infrared light. FIG. 2 shows a more detailed view of the light source 114 embodied as a phosphor LED 122.

Generally, the light source 114 can be embodied in various ways. Thus, the light source 114 can, for example, be part of the spectrometer device 110 in a housing 126 of the spectrometer device 110, as illustrated in FIG. 1. Alternatively or additionally, however, the at least one light source 114 can also be arranged outside the housing 126, for example as a separate light source 114 (not shown). The light source 114 can be arranged separately from the object 110 and illuminate the object 110 from a distance, as indicated in FIG. 1.

Illumination light 116 generated by the light source 114 may propagate from the light source 114 to the object 112. In FIG. 1, the illumination light 116 generated by the light source 114 and propagating to the object 112 is illustrated by an arrow. The object 112 specifically may comprise at least one sample, which may fully or partially be analyzed by spectroscopic methods.

As apparent from FIG. 1, the spectrometer device 110 further comprises at least one detector 128 configured for detecting detection light 130 from the object 112. While light propagating from the light source 114 to the object 112 may be referred to as illumination light 116, light propagating from the object 112 to the detector 128 may be denoted as “detection light” 130. In FIG. 1, the detection light 130 is illustrated by an arrow. The detection light 130 may comprise at least one of illumination light 116 reflected by the object 112, illumination light 116 scattered by the object 112, illumination light 116 transmitted by the object 112, luminescence light generated by the object 112, e.g. phosphorescence or fluorescence light generated by the object 112 after optical, electrical or acoustic excitation of the object 112 by the illumination light 116 or the like. Thus, the detection light 130 may directly or indirectly be generated through the illumination of the object 112 by the illumination light 116.

The detector 128 may be or may comprise at least one optical detector 132. The optical detector 132 may be configured for determining at least one optical parameter, such as an intensity and/or a power of light by which at least one sensitive area of the detector 132 is irradiated. More specifically, the optical detector 132 may comprise at least one photosensitive element and/or at least one optical sensor, such as at least one of a photodiode, a photocell, a photosensitive resistor, a phototransistor, a thermophile sensor, a photoacoustic sensor, a pyroelectric sensor, a photomultiplier and a bolometer. The detector 128, thus, may be configured for generating at least one detector signal, more specifically at least one electrical detector signal, in the above-mentioned sense, providing information on at least one optical parameter, such as the power and/or intensity of light by which the detector 128 or a sensitive area of the detector 128 is illuminated.

The detector 128 may comprise one single optically sensitive element or area or a plurality of optically sensitive elements or areas. As indicated in FIG. 1, the detector 130 may comprise at least one detector array, more specifically an array of photosensitive elements 134. Each of the photosensitive elements 134 may be configured for generating at least one detector signal. In particular, each of the photosensitive elements 134 may comprise at least a photosensitive area, which may be adapted for generating an electrical signal depending on the intensity of the incident light, wherein the electrical signal may, in particular, be provided to an evaluation unit 136 of the spectrometer device, as will be outlined in further detail below.

In case the detector 128 comprises the array of optically sensitive elements 134, the detector 128, may e.g. be selected from any known pixel sensor, specifically from a CCD chip or a CMOS chip. As an alternative, the detector 128 generally may be or comprise a photoconductor, in particular an inorganic photoconductor, especially PbS, PbSe, Ge, InGaAs, ext. InGaAs, InSb, or HgCdTe. As a further alternative it may comprise at least one of pyroelectric, bolometer or thermopile detector elements.

The spectrometer device 110 comprises at least one evaluation unit 136 for evaluating at least one detector signal generated by the detector 128 and for deriving the spectroscopic information on the object 112 from the detector signal. The detector 128 may directly or indirectly provide the detector signals to the evaluation unit 136. Thus, the detector 128 and the evaluation unit 136 may be directly or indirectly connected, as indicated by arrows in FIG. 1. The detector signal may be used as a “raw” detector signal and/or may be processed or preprocessed before further use, e.g. by filtering and the like. Thus, the detector 128 may comprise at least one processing device and/or at least one preprocessing device, such as at least one of an amplifier, an analogue/digital converter, an electrical filter and a Fourier transformation.

As shown in FIG. 1, the spectrometer device 110 further comprises at least one driving unit 138 for electrically driving the light source 114. The spectrometer device 110 comprises at least one measurement unit 139. The measurement unit 139 may be configured for generating at least one item of information on at least one electrically measurable quantity, in particular a forward voltage, required for driving the light-emitting diode 118. The measurement unit 139 may be an element of the driving unit 138, as indicated in FIG. 1. Particularly, the driving unit 138 may be configured for providing an electrical current to the LED 118, specifically for controlling an electrical current through the LED 118. Therein, as an example, the driving unit 138 may be configured for adapting and measuring a voltage provided to the LED 118, the voltage being required for achieving a specific electrical current through the LED 118. The driving unit 138, specifically, may comprise one or more of: a current source 140, a voltage source, a current measurement device, such as an Ampere-meter, a voltage measurement device 142, such as a Voltmeter, a power measurement device. Specifically, the driving unit 138 may comprise at least one current source 140 for providing at least one predetermined current to the LED 118, wherein the current source 140 specifically may be configured for adjusting or controlling a voltage applied to the LED 118 in order to generate the predetermined current. The driving unit 138, as an example, may comprise one or more electrical components, such as integrated circuits, for driving the light source 114. The driving unit 138 may be fully or partially integrated into the light source 114 or may be separated from the light source 114, the latter configuration being illustrated in FIG. 1.

As outlined above, the driving unit 138 may be further configured for generating at least one item of information on at least one electrically measurable quantity, in particular a forward voltage, required for driving the light-emitting diode 118. The forward voltage may be applied to the LED in the forward direction, i.e. as with a positive contact of a voltage or current source 140 applied to a p-layer of the LED 118 and a negative contact applied to the n-layer of the LED 118, in order to generate a predetermined electrical current through the LED 118. As an example, the predetermined current defining the forward voltage may be a current, which is known to generate a predetermined light output of the light source 114 and/or of the light-emitting diode 118.

For generating the at least one item of information on the at least one electrically measurable quantity, in particular the forward voltage, required for driving the light-emitting diode 118, e.g. for driving the LED 118 with a predetermined electrical current in the forward direction, the measurement unit 139 may comprise one or more measurement devices or measurement elements, such as one or more voltage measurement devices 142. The at least one item of information on the at least one electrically measurable quantity, in particular the forward voltage, as an example, may be provided by the measurement unit 139 in the form of at least one electrical signal and/or electrical information, e.g., comprising one or both of an analogue signal and a digital signal. The electrical signal comprising the at least one item of information on the at least one electrically measurable quantity, in particular the forward voltage, may directly or indirectly be provided to the evaluation unit 136. The electrical signal may be time-dependent or static.

As outlined above, and as shown in FIG. 1, the spectrometer device 110 comprises the at least one evaluation unit 136 for evaluating at least one detector signal generated by the detector 128 and for deriving the spectroscopic information on the object 112 from the detector signal. The evaluation unit 136 is configured for taking into consideration wavelength correction information, particularly derived from the at least one detector signal, when deriving the spectroscopic information from the detector signal.

The evaluation unit 136 is configured for determining the wavelength correction information by using an emission peak 193 position of at least one emission band in a power spectral density distribution over the wavelength of the light 116, 130, 256 generated by the light source 114. The emission band is a characteristic, particular only and/or exclusively, of the secondary light generated by the material of the phosphor.

The emission peak 193 position of the at least one emission band in the power spectral density distribution over the wavelength of the light 116, 130, 256 that is used for determining the wavelength correction information may be used for calibrating the wavelength of the spectroscopic information. The light may be the illumination light 116 and/or may be generated by the illumination light 116.

The at least one evaluation unit 136 may be configured for determining the wavelength correction information in the field.

The at least one detector 128 may be configured for generating the at least one detector signal by detecting at least one of:
illumination light 116 from the light source 114,
detection light 130 from the object 112; or
light 256 from at least one reference target 254;
   wherein the evaluation unit 136 may be configured for determining the wavelength correction information, particularly determined from the emission peak 193 position, of the at least one emission band in the power spectral density distribution over the wavelength, of the respective detected light 116, 130, 256.

The at least one detector signal evaluated for deriving the spectroscopic information on the object 112 may comprise the wavelength correction information. The emission peak 193 position of the at least one emission band in the power spectral density distribution over the wavelength of the respective detected light 116, 130, 256 may be detected by the at least one detector 128 prior to deriving the spectroscopic information on the object 112.

The evaluation unit 136 may further be configured for taking into consideration the item of information on the at least one electrically measurable quantity, in particular the forward voltage, when deriving the spectroscopic information from the detector signal. Specifically, the evaluation unit 136 may be configured for processing at least one input signal and to generate at least one output signal thereof. The at least one input signal, as an example, may comprise at least one detector signal provided directly or indirectly by the at least one detector 128 and, additionally, at least one signal directly or indirectly provided by the measurement unit 139, the signal comprising the at least one item of information on the at least one electrically measurable quantity, in particular the forward voltage. The arrows between the driving unit 138, which comprises the measurement unit 139 in the embodiment illustrated in FIG. 1, and the evaluation unit 136 in FIG. 1 illustrate the process of providing to the evaluation unit 136 and/or retrieving by the evaluation unit 136 the signal comprising the at least one item of information on the at least one electrically measurable quantity, in particular the forward voltage.

The evaluation unit 136 may be or may comprise one or more integrated circuits, such as one or more application-specific integrated circuits (ASICs), and/or one or more data processing devices 144, such as one or more of computers, digital signal processors (DSP), field programmable gate arrays (FPGA), preferably one or more microcomputers and/or microcontrollers. Additional components may be comprised, such as one or more preprocessing devices 146 and/or data acquisition devices, such as one or more devices for receiving and/or preprocessing of the detector signals, such as one or more AD-converters and/or one or more filters. Further, the evaluation unit may comprise one or more data storage devices 148, as shown in FIG. 1. Further, the evaluation unit 136 may comprise one or more interfaces, such as one or more wireless interfaces and/or one or more wire-bound interfaces.

Specifically, the evaluation unit 136 may be configured, e.g. by software programming, for determining at least one correction from the item of information on the at least one electrically measurable quantity, in particular the forward voltage, specifically a correction based on a model describing spectral properties of the light source 114 as a function of the at least one electrically measurable quantity, in particular the forward voltage. The evaluation unit 136 further may be configured for correcting the at least one detector signal, by using the correction. The correction specifically may comprise multiplying the at least one detector signal with at least one correction factor as described in detail above and as will be described further below in an exemplary fashion. The evaluation unit 136 specifically may be configured for using the corrected detector signal for deriving the spectroscopic information.

As described above in more detail, the detector 128 may specifically comprise an array of photosensitive elements 134. Each of the photosensitive elements may be configured for generating at least one detector signal. The evaluation unit 136 may be configured for individually correcting each of the detector signals and for combining the detector signals for deriving the spectroscopic information. The spectrometer device 110 may be configured such that the photosensitive elements of the detector 128 are sensitive to differing spectral ranges of the light from the object 112. In particular, the detector 128 may be configured for generating detector signals for at least two differing spectral ranges of the light from the object, specifically at least one of sequentially and simultaneously. The spectrometer 110 specifically may comprise at least one filter element 150 disposed in a beam path of the light from the object. The filter element 150 specifically may be configured such that each of the photosensitive elements is exposed to an individual spectral range of the light from the object 112.

The spectrometer device 110 further may comprise one or more optical components 151, e.g. such as one or more of at least one mirror, at least one lens, at least one aperture and at least one wavelength-selective element 152. Specifically, the one or more optical components 151 may be arranged in at least one of the beam path of the illumination light 116 and the beam path of the detection light 130. The spectrometer device 110 may in particular comprise the at least one wavelength-selective element 152. The wavelength-selective element 152 specifically may be selected from the group of a tunable wavelength-selective element 152 and a wavelength-selective element 152 having a fixed transmission spectrum. By using a tunable wavelength-selective element 152, as an example, differing wavelength ranges may be selected sequentially, whereas, by using a wavelength-selective element 152 having a fixed transmission spectrum, the selection of the wavelength ranges may be fixed and may, however, be dependent e.g. on a detector position. The wavelength-selective element 152 may be used for separating incident light into a spectrum of constituent wavelength signals whose respective intensities are determined by employing a detector, e.g. the detector 128 of the spectrometer device 110, which may comprise the array of photosensitive elements 134. The at least one wavelength-selective element 152 may e.g. comprise at least one of a filter, a grating and a prism. The wavelength-selective element 152 may specifically comprise at least one of a wavelength-selective element 152 disposed in the beam path of the illumination light 116 and a wavelength-selective element 152 disposed in the beam path of the detection light 130. FIG. 1 illustrates an embodiment of the spectrometer device 110 with one wavelength-selective element 152 arranged in the beam path of the illumination light 116, and one wavelength-selective element 152 arranged in the beam path of the detection light 130.

The spectrometer device 110 as represented in a schematic fashion in FIG. 1 is configured for obtaining spectroscopic information on the at least one object 112. In particular, the spectrometer device may be configured for obtaining an item of information, e.g. on at least one object and/or radiation emitted by at least one object, characterizing at least one optical property of the object, more specifically at least one item of information characterizing, e.g. qualifying and/or quantifying, at least one of a transmission, an absorption, a reflection and an emission of the at least one object. As an example, the at least one item of spectral information may comprise at least one intensity information, e.g. information on an intensity of light being at least one of transmitted, absorbed, reflected or emitted by the object, e.g. as a function of a wavelength or wavelength sub-range over one or more wave-lengths, e.g. over a range of wavelengths. Thus, the spectrometer device 110 may be configured for acquiring at least one spectrum or at least a part of a spectrum of detection light 130 propagating from the object 112 to the detector 128. The spectrum may describe the radiometric unit of spectral flux, e.g. given in units of watt per nanometer (W/nm), or other units, e.g. as a function of the wavelength of the detection light.

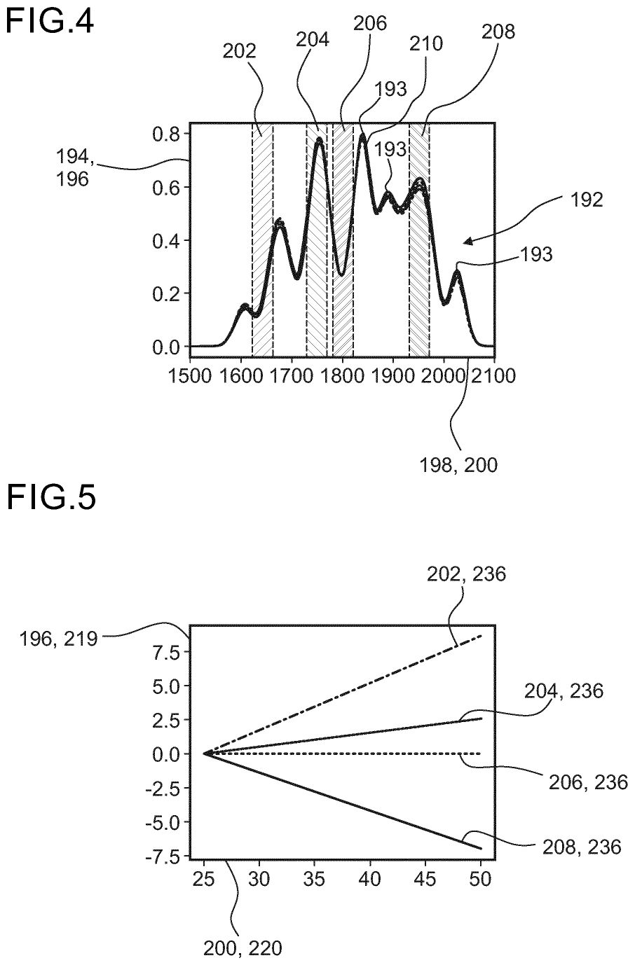

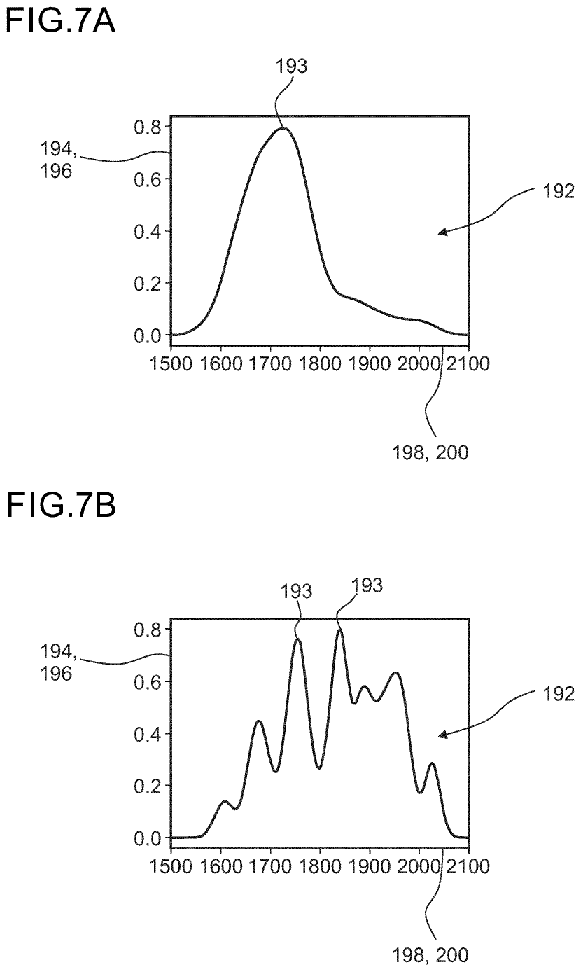

Thus, the spectrum may describe the optical power of light, e.g. in the NIR spectral range, in a specific wavelength band. The spectrum may contain one or more optical variables as a function of the wavelength, e.g. the power spectral density, electric signals derived by optical measurements and the like. Examples of spectra are shown e.g. in FIGS. 4, 7A and 7B. The spectrometer device 110 may specifically be a portable spectrometer device 110, which may in particular be used in the field.

In FIG. 2, a schematic cross-sectional view of a light source 114 is shown. The at least one light source 114 of the spectrometer device 110 may be configured for generating or providing to electromagnetic radiation in one or more of the infrared, the visible and the ultraviolet spectral range. Due to the fact that many material properties or properties on the chemical constitution of many objects 112 may be derived from the near infrared spectral range, light used for the typical purposes of the present invention is light in the infrared (IR) spectral range, more preferred, in the near infrared (NIR) and/or the mid infrared spectral range (MidIR), especially the light having a wavelength of 1 μm to 5 μm, preferably of 1 μm to 3 μm. The light source 114 comprises the at least one light-emitting diode 118 and the at least one luminescent material 120 for light-conversion of primary light generated by the light-emitting diode 118. The LED 118 and the luminescent material 120, together, may form the phosphor LED 122, as described above.

The phosphor LED 122 as illustrated in FIG. 2 may comprise one or more functional components. Specifically, the phosphor LED 122 may comprise one or more substrates 154, specifically one or more electrically insulating substrates 154. In particular, the phosphor LED 122 may comprise one or more ceramic substrates 156, as shown in FIG. 2. The substrate 154 may be configured for holding the at least one LED die 124 and the at least one luminescent material 120. Further, the at least one substrate 154 may hold or comprise one or more components of electrical connectivity, such as one or more contact pads 158 as shown in FIG. 2 and/or one or more electrical leads, such as one or more metallic contacts and/or one or more metallic leads. The substrate 154 may be configured to serve as a heat sink. Heat may be generated in the LED die 124, such as due to a limited conversion of electrical energy into photonic energy, as well as in the luminescent material 120, e.g. during the conversion process. Said heat may be dissipated in the substrate 154, such as in ceramic substrate.

As shown in FIG. 2, the phosphor LED 122 may comprise the light-emitting diode 118. The light-emitting diode 118 may be configured for converting electrical current into primary light, such as blue primary light, using at least one LED chip and/or the at least one LED die 124 as illustrated in FIG. 2. Specifically, p-n-diodes may be used. As an example, one or more LEDs 118 selected from the group of an LED 118 on the basis of indium gallium nitride (InGaN), an LED 118 on the basis of GaN, an LED 118 on the basis of InGaN/GaN alloys or combinations thereof and/or other LEDs 118 may be used. Additionally or alternatively, quantum well LEDs 118 may also be used, such as one or more quantum well LEDs 118 on the basis of InGaN. Additionally or alternatively, Superluminescence LEDs (sLED) and/or Quantum cascade lasers may be used. As further apparent from FIG. 2, the phosphor LED may comprise the at least one luminescent material 120 configured for light-conversion of the primary light generated by the light-emitting diode 118. Various types of conversion and/or luminescence are known and may be used in the context of the present invention. Specifically, the luminescent material 120 may comprise at least one of: Cerium-doped YAG (YAG:Ce³⁺, or Y₃Al₅O₁₂:Ce³⁺); rare-earth-doped Sialons; copper- and aluminium-doped zinc sulfide (ZnS:Cu,Al).

The luminescent material 120 specifically may form at least one layer. Generally, various alternatives of positioning the luminescent material 120 with respect to the light-emitting diode 118 are feasible, alone or in combination. Firstly, the luminescent material 120, e.g., at least one layer of the luminescent material 120, such as the phosphor, may be positioned directly on the light-emitting diode 118, e.g. with no material in between the LED 118 and the luminescent material 120 or with one or more transparent materials in between, such as with one or more transparent materials, specifically transparent for the primary light, in between the LED and the luminescent material 120. Thus, as an example, a coating of the luminescent material 120 may be placed directly or indirectly on the LED 118 (not shown). Additionally or alternatively, the luminescent material 120, as an example, may form at least one converter body 160, such as at least one converter disk, which may also be referred to as converter platelet. The converter body 160 may be placed on top of the LED 118, e.g. by adhesive attachment of the converter body 160 to the LED 118, as illustrated in FIG. 2. Additionally or alternatively, the luminescent material 120 may also be placed in a remote fashion, such that the primary light from the LED 118 has to pass an intermediate optical path before reaching the luminescent material 120 (not shown). Again, as an example, the luminescent material in the remote placement may form a solid body or converter body 160, such as a disk or converter disk. In the intermediate optical path, one or more optical elements may be placed, such as one or more of a lens, a prism, a grating, a mirror, an aperture or a combination thereof. Thus, specifically, an optical system having imaging properties may be placed in between the LED 118 and the luminescent material 120, in the intermediate optical path. Thereby, as an example, the primary light may be focused, or bundled onto the converter body 160.

In the light source 114, specifically the phosphor LED 122, the at least one luminescent material 120 may be located with respect to the light-emitting diode 118 such that a heat transfer from the light-emitting diode 118 to the luminescent material 120 is possible. More specifically, the luminescent material 120 may be located such that a heat transfer by one or both of thermal radiation and heat conduction is possible, more preferably by heat conduction. Thus, as an example, the luminescent material 120 may be in thermal contact and/or in physical contact with the light-emitting diode 118 as illustrated in FIG. 2. Thereby, generally, a temperature of the luminescent material 120 and a temperature of the light-emitting diode 118 may be coupled.

As illustrated in FIG. 2, the light source 114, specifically the phosphor LED 122, may comprise further components such as at least one side coat 162 covering at least one side, such as a top side, a bottom side and/or one or more lateral sides of at least of: the substrate 154, the contact pad 158, the light-emitting diode 118 and the luminescent material 120. Specifically, the side coat 162 may cover gaps and/or interspaces that may be present in the layered set-up of the light source 114 as shown in FIG. 2. Further components of the light source 114, specifically components, which are not shown in FIG. 2, are feasible. Generally, the light source 114, in particular the phosphor LED 122, may be packaged in one housing (not shown in FIG. 2) or may be unpackaged. Thus, the LED 118 and the at least one luminescent material 120 for light-conversion of the primary light generated by the light-emitting diode 118 may specifically be housed in a common housing. Alternatively, however, the LED 118 may also be an unhoused or bare LED 118, as illustrated in FIG. 2.

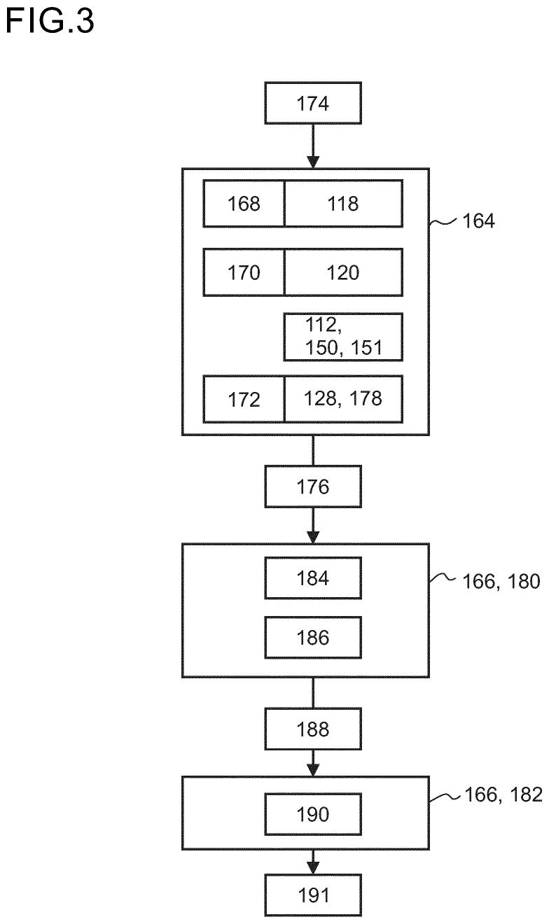

The schematic flowchart of FIG. 3 illustrates the process of generating the detector signal as well as processing of the detector signal, e.g. to generate a corrected signal. Specifically, hardware components 164, which may take part in the process or generating and/or preprocessing the detector signal as well as software components 166, which may take part in processing and/or correcting the detector signal, are illustrated in FIG. 3. The hardware components 164, also simply referred to as “hardware” 164, may specifically comprise the at least one light-emitting diode 118 of the spectrometer device 110, in particular a blue LED 118, configured for emitting blue primary light. The hardware components 164 may further comprise the luminescent material 120, also referred to as LED phosphor, the object 112 as well as one or more optical components 151, e.g. the at least one wavelength-selective element 152, and the detector 128.

As part of the correction that may be performed by the evaluation unit 136, a correction for temperature changes may be performed, even for local temperature changes within the light source 114, which may have an impact on the emission characteristics of the light source 114. In addition to the hardware components 164, temperatures for selected hardware components 164 are indicated in FIG. 3. The hardware components 164 may have differing or identical temperatures, e.g. depending on an arrangement of the hardware components 164, such as their relative positions and distances in the spectrometer device 110. Specifically, as described above, the temperature of the luminescent material 120 and the temperature of the light-emitting diode 118 may be coupled, e.g. due to heat transfer by one or both of thermal radiation and heat conduction between the light-emitting diode 118 and the luminescent material 120. Thus, in particular, the temperature of the LED 118, which may also be referred to as “Tₚₙ”, and the temperature of the luminescent material 120, which may also be referred to as “T_{Ph}”, may be similar or even identical. In FIG. 3, the temperature of the LED 118 is indicated with reference sign 168, the temperature of the luminescent material 120 is indicated with reference sign 170, and the temperature of the detector 128, also referred to as “T_{D}”, is indicated with reference sign 172.

The LED 118 may emit primary light when an electrical current flows through the LED 118, e.g. as a result of an appropriate voltage applied to the LED by the driving unit 138 in order to generate a specific electrical current, such as a predetermined electrical current. A target signal Sₜ may be provided as indicated in FIG. 3 by reference sign 174, e.g. to the driving unit 138, to drive the LED 118 to emit blue primary light. The target signal Sₜ 174 may in particular be a predetermined current value that is to be generated through the LED 118, e.g. by applying an appropriate voltage. The predetermined current value may in particular be in the range from 10 mA to 500 mA, more specifically in the range from 100 mA to 300 mA, e.g. a current value of 50 mA. Thus, the predetermined current may be known to generate a predetermined light output of the LED 118, such as blue primary light. The LED 118 may be at the temperature “Tₚₙ” indicated by reference sign 168. The blue primary light may be converted by the luminescent material 120 into secondary light, such as into light in the infrared spectral range. The luminescent material 120 may be at the temperature “Tₚₕ” indicated by reference sign 170. The illumination light 116 generated by the light source 114, which may comprise at least one of the primary light or a part thereof, the secondary light or a part thereof, or a mixture of both, may illuminate the object 112. For directing the illumination light 116, one or more optical components 151, such as one or more mirrors, lenses, wavelength selective elements 152 or other optical components 151 may be used, e.g. by placing the optical components 151 in the beam path of the illumination light 116. The detection light from the object 112, e.g. reflected light, may be directed to the detector 128. In the beam path of the detection light 130, again, optionally, one or more optical components 151 may be used. As an example, one or more wavelength-selective elements 152 may be used, such as one or more dispersive elements, e.g. for splitting the detection light 130 into its spectral components.

As described above in more detail, the detector 128 may e.g. comprise an array of photosensitive elements 134. Specifically, the detector 128 may be or may comprise a pixel sensor, such as a CCD chip or a CMOS chip, comprising a plurality of pixels arranged on the chip. As an example, each of the pixels may correspond to a predetermined spectral range, e.g. by being sensitive to the predetermined spectral range. The detector 128 may thus generate a detector signal S_{px,i} 176, as indicated in FIG. 3 by reference sign 176, comprising a plurality of detector signals. Thus, each of the plurality of detector signals may correspond to an electronic signal generated by one of the plurality of pixels of the detector 128. Each of the plurality of detector signals may e.g. be given as a numerical value corresponding to a number of counts of the respective pixel as measured e.g. during a predetermined time span. Thus, the detector signal S_{px,i} 176 may specifically be a function of the wavelength of the detection light 130, as indicated by the index “px”. The signal S_{px,i} 176 may further be a function of time, e.g. in the case of time-dependent detector signals, as indicated by the index “i”.

The plurality of signals comprised by the detector signal S_{px,i} 176 may be generated simultaneously or in a temporally successive manner. The detector signal S_{px,i} 176 may be determined using readout electronics 178 as indicated in FIG. 3. The detector signal S_{px,i} 176 may be processed, e.g. as part of the preprocessing and/or as part of further processing steps. As an example, the pixels comprised by the detector 128 may specifically be active pixel sensors, which may be adapted to amplify the electronic detector signal S_{px,i} 176, e.g. as part of a preprocessing process prior to further processing that may e.g. be performed by one or more of the software components 166.

The signal S_{px,i} 176 as generated by the detector 128 may also be referred to as “Frame signal S_{px,i} 176”. FIG. 3 illustrates the process of providing the signal S_{px,i} 176 to one of the software components 166 with an arrow. Specifically, the software components 166 configured for processing and/or correcting the detector signal S_{px,i}, 176 may comprise at least one first software 180, which may also be referred to as “software 1”, and at least one second software 182, which may also be referred to as “software 2”. The first software 180 may be configured for performing at least one first processing step 184, also referred to as “processing 1”, on the detector signal S_{px,i} 176, such as by applying at least one algorithm to the detector signal S_{px,i} 176. Specifically, the first processing step 184 may comprise at least one correction of transient or time-dependent effects. Thus, as an example, the first processing step 184 may comprise one or more of the following: a correction of the dark signal; a correction of dark signal drift; a correction of fluctuation effects; a correction of photodetector response for individual detector elements or individual time steps; a correction of environment-induced, e.g., temperature-induced changes of the photodetector response; an extraction of information for subsequent processing; an addition or multiplication with a parameter, which was generated from information on the at least one electrically measurable quantity, in particular the forward voltage, or on device temperature. The first software 180 may be configured for performing at least one further step comprising at least one fast Fourier transform 186 to the detector signal. Thus, as a result of applying the first processing step 184 and/or the fast Fourier transform 186 to the detector signal S_{px,i} 176, a signal Sₚₓ 188, also referred to as “pixel signal Sₚₓ 188”, may be generated, which may no longer be a function of time. Specifically, the time dependency of the frame signal S_{px,i} 176 may be eliminated by one or more of the steps forming part of the first software component 1 while the wavelength dependency may still be present in the on signal Sₚₓ 188 as indicated by the index “pn”. FIG. 3 further illustrates the process of providing the signal Sₚₓ 188 to the second software 182 with an arrow. The second software 182 may be configured for performing at least one second processing step 190, also referred to as “processing 2”, on the signal Sₚₓ 188, such as by applying at least one algorithm to the signal Sₚₓ 188, thereby generating at least one corrected signal S_{px, corr} 191. Specifically, the second processing step 190 may comprise one or more of the following: a correction of the dark signal; a correction of dark signal drift; a correction of fluctuation effects; a correction of photodetector response for individual detector elements or individual time steps; a correction of environment-induced, e.g., temperature-induced changes of the photodetector response; an extraction of information for subsequent processing; a manipulation with at least one parameter, for example an addition or multiplication with a parameter, which was generated from information on the at least one electrically measurable quantity, in particular the forward voltage, or on device temperature. In particular, the corrected signal S_{p, corr} 191 may comprise a plurality of corrected signals, such as a plurality of corrected electronic signals. Each of the plurality of corrected signals may specifically correspond to a corrected number of counts of the respective pixel.

The spectrometer device 110 comprises the at least one evaluation unit 136 for evaluating the at least one detector signal generated by the detector 128 and for deriving the spectroscopic information on the object 112 from the detector signal. The evaluation unit 136 is configured for taking into consideration the item of information on the at least one electrically measurable quantity, in particular the forward voltage when deriving the spectroscopic information from the detector signal. The evaluation unit 136 may in particular be configured by software programming for evaluating and/or processing the detector signal as part of the first processing step 184 of the at least one first software 180. The evaluation unit 136 may specifically be configured for determining the at least one correction from the item of information on the at least one electrically measurable quantity, in particular the forward voltage, and may further be configured for correcting the at least one detector signal, by using the correction. Thus, the evaluation unit 136 may process and correct the signal Sₚₓ 188 to generate a signal S_{px,i, corr}, which may then e.g. be further processed such as by applying the fast Fourier transform 186.

Both the light-emitting diode 118 and the luminescent material 120 may be based on different materials and/or different compositions of materials, e.g. as described in more detail above, which, generally, may affect and influence the spectrum 192 of the phosphor LED 122. However, the spectrum 192 or the spectral properties of a specific phosphor LED 122 may change with temperature, even when being operated at a specific, predetermined current. These changes may include shifts of the emission peaks 193, broadening or narrowing of the spectrum 192, increases or decreases of the emission and the like. In many cases, however, the emission at some wavelengths is affected to a larger extent than the emission at other wavelengths. This effect is illustrated by the diagram shown in FIG. 4, which represents a superposition of spectra 192 of infrared radiation of a phosphor LED 122 at various temperatures. Specifically, the diagram in FIG. 4 shows the power spectral density (PDS) 194 in units of microwatt per nanometer (μW/nm) on the y-axis 196 as a function of the wavelength 198 given in nanometers on the x-axis 200. For the represented spectra 192 the temperature of the phosphor LED 122 generating the illumination light 116 ranges from 25° C. to 50° C. Typically, there is within the spectrum 192, a specific central wavelength or an emission peak 193 position, where the power spectral density typically does not change with temperature. Each wavelength therefore typically has its own temperature coefficient, regarding to the increment/decrement of the power. Therefore, the shape of the spectrum 192 changes with temperature as apparent from FIG. 4. To visualize this effect even more clearly, a number of four specific wavelength intervals, each centering around one of four specific wavelengths ranging across the spectrum 192 are indicated in FIG. 4. The wavelength intervals are delimited by dashed lines. Specifically, the following four wavelengths and their respective intervals are marked with the following reference signs: 1643 nm is indicated by reference sign 202, 1750 nm is indicated by reference sign 204, 1802 nm is indicated by reference sign 206, and 1950 nm is indicated by reference sign 208. As may be derived from FIG. 4, the emission peak 193 position of the respective feature 210 in the at least one emission band in the distribution of the power spectral density 194 over the wavelength of the light 116, 130, 256 used for determining the wavelength correction information may be independent of a temperature of the light source 114. For each of these wavelengths, the emission power change normalized to the emission power change at 25° C. is shown in the diagram in FIG. 5 as a function of temperature over a temperature range from 25° C. to 50° C. In the diagram of FIG. 5 the emission power change normalized to the emission power change at 25° C. given in percent is shown on the y-axis 196 and represented by reference sign 219, while the temperature in ° C., represented by reference sign 220, is indicated on the x-axis 200.

The lines in the diagram in FIG. 5 indicate fitted curves 236. As apparent from FIG. 5, the emission power at the central wavelength of 1802 nm may change very little over the observed temperature range (that is, the emission power change is zero or close to zero), while the emission power change may change considerably for other wavelengths, e.g. for 1643 nm or 1953 nm.

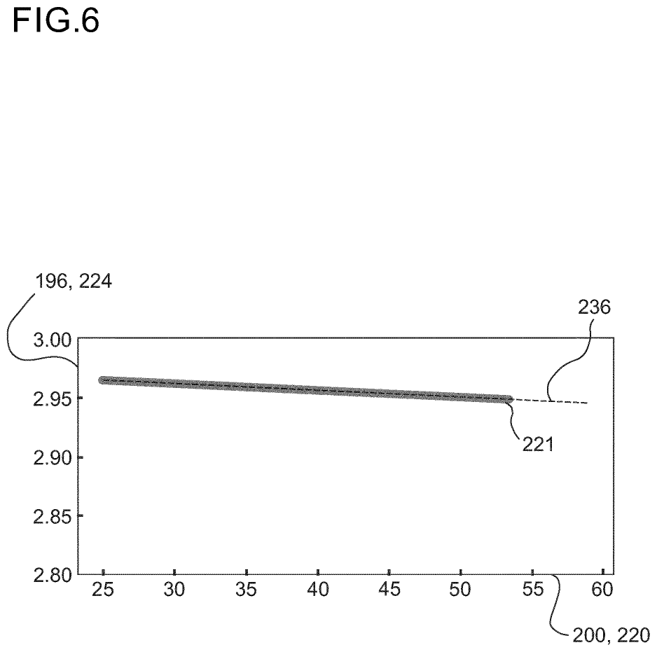

When generating a specific current through a light-emitting diode 118, such as an electrical current at a specific, predefined value by applying to the light-emitting diode 118 a forward voltage, the appropriate forward voltage may be a function of the temperature of the light-emitting diode 118. Thus, when applying the same current to the light-emitting diode 118, the forward voltage of the LED 118 typically decreases while temperature increases. Each type of the LED 118 has its own characteristic forward voltage to temperature curve. Typically, the forward voltage of the LED 118 linearly decreases with rising temperature, such as with a slope in the range of 1·10⁻⁴ to 1·10⁻³ V/K. FIG. 6 illustrates this relationship for a specific LED 118. In particular, the diagram of FIG. 6 shows the forward voltage applied to an LED 118 for the generation of a direct current of 150 mA through the LED 118 as a function of the temperature of the LED 118. The forward voltage in the units of Volt is represented by reference sign 224 on the y-axis 196. The temperature in ° C. is indicated by reference sign 220 on the x-axis 200. As apparent from FIG. 6, the forward voltage, in this case, decreases linearly with increasing temperature. The curve in FIG. 5, may be described by the following equation:

$${U}_{f} = - 0.00059 \frac{V}{° C .} * T + 2.98$$

wherein U_{f} represents the forward voltage and T represents the Temperature. In the diagram in FIG. 6, measuring points 221 represented by grey, filled circles are shown as well as a dashed line corresponding to the above given fitted curve 236. Instead of a relation and/or curve between the forward voltage and the temperature as described in an exemplary fashion above, a relation between another electrically measurable quantity required for driving the light source and the temperature may be used, e.g. a fed in electrical power; a current, resistance, inductance, capacitance and the like.

Thus, by using the at least one electrically measurable quantity, in particular the forward voltage, as a correction parameter, an individual temperature correction of the spectrum 192 at the different wavelengths may be performed. Specifically, the evaluation unit 136 may be configured for individually correcting the plurality of detector signals of the detector signal S_{px,i} and for combining the individually-corrected detector signals for deriving the spectroscopic information. As outlined above, the individual correction may be performed by using the array of photosensitive elements 134, wherein each of the photosensitive elements may be configured for generating at least one detector signal and wherein each of the detector signals may individually be corrected by using the at least one electrically measurable quantity, in particular the forward voltage, as a correction parameter. Finally, the corrected detector signals may be combined for deriving the spectroscopic information.

For deriving the spectroscopic information on the object 112, specifically a spectrum, the spectrometer device 110, in particular the evaluation unit 136, may specifically take into account the characteristics of the luminescent material 120 used in the light source 114. As outlined in more detail above, the luminescent material 120 may be configured for absorbing primary photons generated by the light-emitting diode 118 and may, as a reaction, emit secondary photons instantaneously or after a delay or decay time. The signal or emission of the phosphor LED 122 after turning off the forward current may be described using equations (1) and (2) as described above.

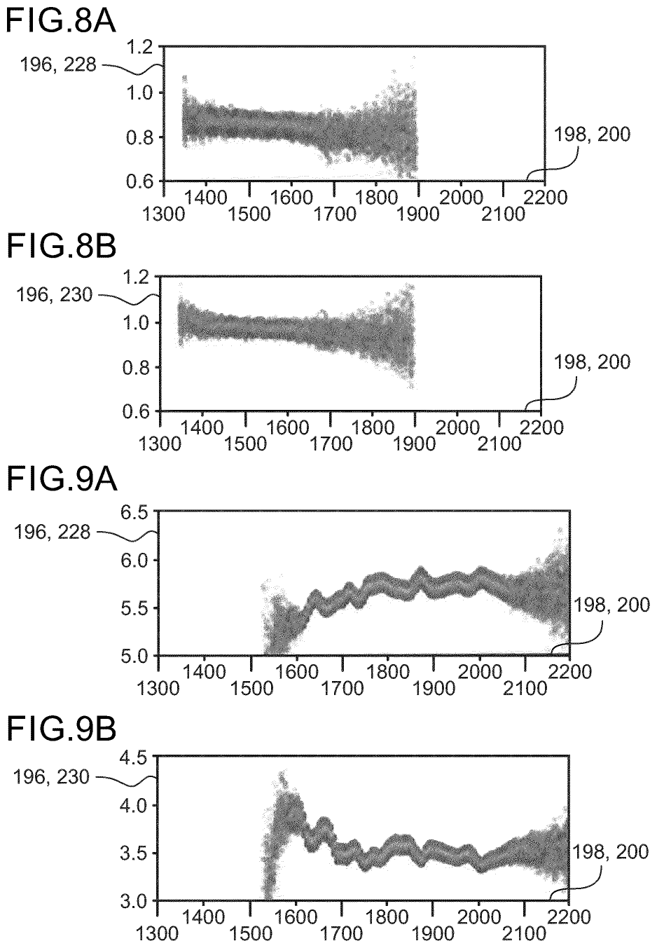

Thus, characteristic for the luminescent material 120 may in particular be the decay constant τ_{d}228, which may describe the typical time of an afterglow of the luminescent material 120, as well as the growth constant τ_{g}, which may describe the typical time for reaching a saturation of the emission of converted light. The time constants τ_{d} and τ_{g} typically differ between different phosphor LEDs 122 and/or between different types of the luminescent material 120. Additionally, decay constant τ_{d} and growth constant τ_{g} may depend on the wavelength. The time constants typically are extracted from step response of the optical signal by applying/shutting off the forward current. FIGS. 7A and 7B show spectra 192 of two different types of phosphor LEDs 122, which emit light in the near infrared range. Specifically the power spectral density is shown as a function of the wavelength, which is given in nm. As apparent from FIGS. 7A and 7B the spectra 192 of the two different phosphor LEDs 122 differ. Thus, as an example, the spectrum 192 shown in FIG. 7A reflects a high emission in the range from 1400 nm to 1600 nm, while the emission in this region is negligible for the phosphor LED 122, whose spectrum 192 is shown in FIG. 7B. The decay constant τ_{d} and the growth constant τ_{g} of the phosphor LED 122, whose spectrum is shown in FIG. 7A, are given as a function of the wavelength in FIGS. 8A and 8B, respectively. The decay constant τ_{d} and the growth constant τ_{g} of the phosphor LED 122, whose spectrum is shown in FIG. 7B, are given as a function of the wavelength in FIGS. 9A and 9B, respectively. Specifically, FIGS. 8A and 9A show the respective decay constants τ_{d} in ms, indicated by reference sign 228, on the y-axis 196 versus the wavelength in nm 198 on the x-axis 200; and FIGS. 8B and 9B show the respective growth constants τ_{g} in ms, indicated by reference sign 230, on the y-axis 196 versus the wavelength in nm 198 on the x-axis 200. Data points from different repetition measurements are marked in different shades of grey.

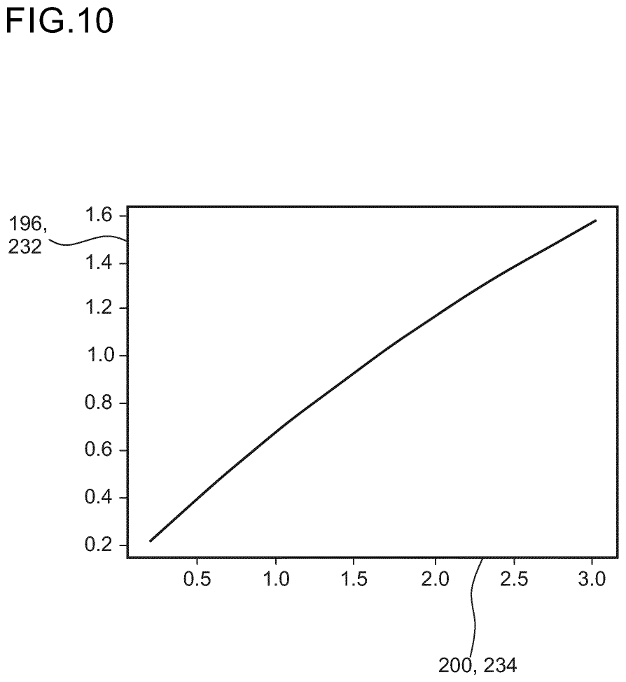

A further characteristic of the LED 118 is the light output power as a function of the forward current. Thus, generally, by increasing the forward current, specifically the input current, the power emitted by the LED 118 is increased. The shape, e.g. the slope, of the curve of the light output as a function of the forward current is characteristic to the individual LED 118. FIG. 10 shows an example of such a curve. Specifically, in the diagram in FIG. 10, the normalized light output 232 of a phosphor LED is shown as a function of the forward current 234, which is given in Ampere.

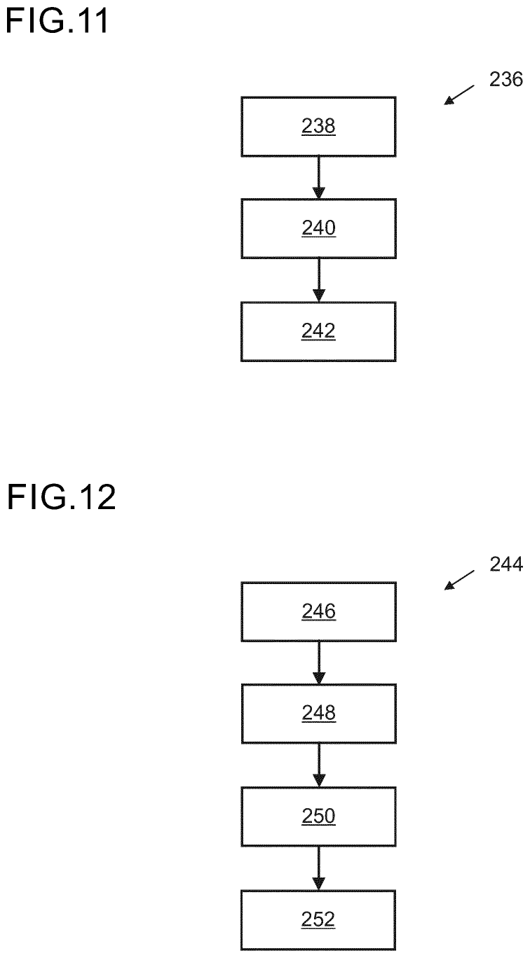

In FIG. 11, a method 236 for calibrating a spectrometer device 110 for obtaining spectroscopic information on at least one object 112 is shown. The method 236 is comprising:
a. in a step a. 238: electrically driving at least one light source 114 by using at least one driving unit 138, the light source 114 comprising at least one light-emitting diode 118 and at least one luminescent material 120 for light-conversion of primary light generated by the light-emitting diode 118;
b. in a step b. 240: detecting light 116, 130,256 by using at least one detector 128 and, thereby, generating at least one detector signal; and
c. in a step c. 242: evaluating the at least one detector signal generated by the detector 128 by using at least one evaluation unit 136, and determining wavelength correction information by using, particularly a feature 210 position, more particularly an emission peak 193 position of at least one emission band in, a power spectral density distribution over the wavelength of the light 116, 130, 256 generated by the light source 114, and determining the wavelength correction information by using an emission peak 193 position of at least one emission band in a power spectral density distribution over the wavelength of the light 116, 130, 256 generated by the light source 114, wherein the luminescent material 120 is phosphor, wherein the emission band is a characteristic of the secondary light generated by the material of the phosphor.

The power spectral density distribution over the wavelength of the detected light 116, 130,256 may be determined by using the at least one detector 128.

In FIG. 12, a method 244 of obtaining spectroscopic information on at least one object 112, the method comprising:
1. in a step 1. 246: electrically driving at least one light source 114 by using at least one driving unit 138, the light source 114 comprising at least one light-emitting diode 118 and at least one luminescent material 120 for light-conversion of primary light generated by the light-emitting diode 118;
2. in a step 2. 248: illuminating the object 112 with illumination light 116 generated by the light source 114;
3. in a step 3. 250: detecting light 116, 130,256, by using at least one detector 128, and, thereby, generating at least one detector signal; and
4. in a step 4. 252: evaluating at the least one detector signal by using at least one evaluation unit 136, and deriving the spectroscopic information on the object 112 from the at least one detector signal by using the evaluation unit 136, wherein the spectroscopic information on the object 112 is derived by taking into consideration wavelength correction information, particularly derived from the at least one detector signal.

The wavelength correction information is determined by using a method for calibrating the spectrometer device for obtaining the spectroscopic information on the at least one object. The method may further comprise a step of generating, by using at least one measurement unit, at least one item of information on at least one electrically measureable quantity required for driving the light-emitting diode; wherein the item of information on the at least one electrically measureable quantity, in particular a forward voltage, may be further taken into consideration when deriving the spectroscopic information from the detector signal.

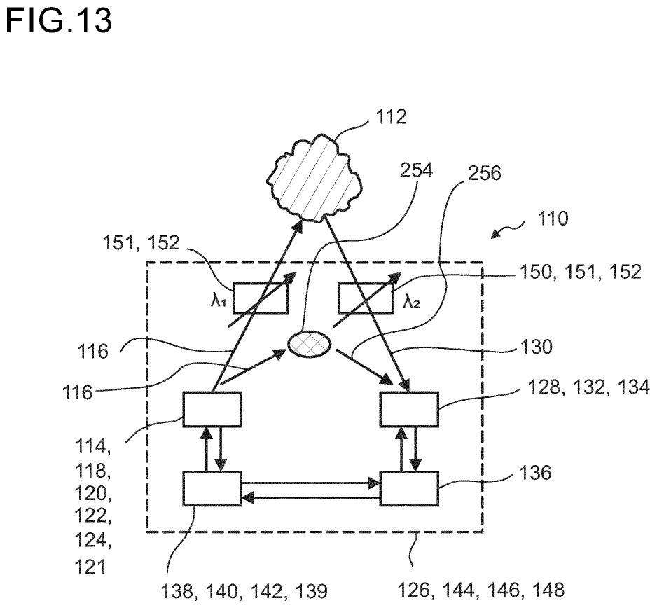

In FIG. 13, a further exemplary spectrometer device 110 is shown. To the extent that the reference signs correspond to those in FIG. 1, reference is made to these. The further spectrometer device 110 additionally comprises a reference target 254. Alternatively, the reference target may be a component extern of the further spectrometer device 110. The reference target 254 may be illuminated by illumination light 116. The detector 128 may detect light 250 from the at least one reference target 248.

### LIST OF REFERENCE NUMBERS

110 spectrometer device
112 object
114 light source
116 illumination light
118 light-emitting diode
120 luminescent material
121 semiconductor material
122 phosphor light-emitting diode
124 LED die
126 housing
128 detector
130 detection light
132 optical detector
134 array of photosensitive elements
136 evaluation unit
138 driving unit
139 measurement unit
140 current source
142 voltage measurement device
144 data processing devices
146 preprocessing devices
148 data storage devices
150 filter element
151 optical component
152 wavelength-selective element
154 substrate
156 ceramic substrate
158 contact pad
160 converter body
162 side coat
164 hardware components
166 software components
168 temperature of the LED
170 temperature of the luminescent material
172 temperature of the detector
174 target signal Sₜ
176 electronic detector signal S_{px,i}
178 readout electronics
180 software 1
182 software 2
184 first processing step
186 fast Fourier transformation
188 pixel signal Sₚₓ
190 second processing step
191 signal S_{px, corr}
192 spectrum
193 peak
194 power spectral density in microwatt per nanometer
196 y-axis
198 wavelength in nm
200 x-axis
202 1643 nm
204 1750 nm
206 1802 nm
208 1950 nm
210 feature
219 emission power change normalized to 25° C. (given in percent)
220 temperature in ° C.
221 measuring points
224 forward voltage in Volt
226 signal in number of counts
228 decay constant τ_{d} in ms
230 growth constant τ_{g} in ms
232 normalized light output
234 forward current in Ampere
236 method for calibrating a spectrometer device
238 step a.: electrically driving at least one light source
240 step b.: detecting light by using at least one detector
242 step c.: evaluating the at least one detector signal
244 method of obtaining spectroscopic information
246 step 1.: electrically driving at least one light source
248 step 2.: illuminating an object with illumination light
250 step 3.: detecting light by using at least one detector
252 step 4.: evaluating at the least one detector signal
254 reference target
256 light from the reference target

1. A spectrometer device for obtaining spectroscopic information on at least one object, the spectrometer device comprising:
i. at least one light source for generating illumination light for illuminating the object, the light source comprising at least one light-emitting diode and at least one luminescent material for light-conversion of primary light generated by the light-emitting diode;
ii. at least one detector for detecting light and, thereby, generating at least one detector signal; and
iii. at least one evaluation unit configured for deriving the spectroscopic information on the object from the at least one detector signal, wherein the evaluation unit is configured for deriving the spectroscopic information on the object by taking into consideration wavelength correction information, wherein the evaluation unit is configured for determining the wavelength correction information by using an emission peak position of at least one emission band in a power spectral density distribution over the wavelength of the light generated by the light source, wherein the luminescent material is phosphor, wherein the emission band is a characteristic of the secondary light generated by the material of the phosphor.

2. The spectrometer device according to claim 1, wherein the emission peak position of the at least one emission band in the power spectral density distribution over the wavelength of the light that is used for determining the wavelength correction information is used for calibrating the wavelength of the spectroscopic information.

3. The spectrometer device according to claim 1, wherein the emission peak position of the at least one emission band in the power spectral density distribution over the wavelength of the light used for determining the wavelength correction information is independent of a temperature of the light source.

4. The spectrometer device according to claim 1, wherein the at least one evaluation unit is configured for determining the wavelength correction information on-line in the field.

5. The spectrometer device according to claim 1, wherein the at least one detector is configured for generating the at least one detector signal by detecting at least one of:
illumination light from the light source,
detection light (130) from the object; or
light from at least one reference target;
wherein the evaluation unit is configured for determining the wavelength correction information by evaluating the respective detected light.

6. The spectrometer device according to claim 1, wherein the at least one detector signal evaluated for deriving the spectroscopic information on the object comprises the wavelength correction information.

7. The spectrometer device according to claim 1, wherein the emission peak position of the at least one emission band in the power spectral density distribution over the wavelength of the respective detected light is detected by the at least one detector prior to deriving the spectroscopic information on the object.

8. The spectrometer device according to claim 1, wherein the spectrometer device is further comprising at least one measurement unit for generating at least one item of information on at least one electrically measurable quantity required for driving the light-emitting diode, wherein the evaluation unit is further configured for taking into consideration the item of information on the at least one electrically measureable quantity when deriving the spectroscopic information from the detector signal.

9. A method for calibrating a spectrometer device for obtaining spectroscopic information on at least one object, the method comprising:
a. electrically driving at least one light source by using at least one driving unit, the light source comprising at least one light-emitting diode and at least one luminescent material for light-conversion of primary light generated by the light-emitting diode;
b. detecting light by using at least one detector and, thereby, generating at least one detector signal; and
c. evaluating the at least one detector signal generated by the detector by using at least one evaluation unit, and determining wavelength correction information by using a power spectral density distribution over the wavelength of the light generated by the light source, and determining the wavelength correction information by using an emission peak position of at least one emission band in a power spectral density distribution over the wavelength of the light generated by the light source, wherein the luminescent material is phosphor, wherein the emission band is a characteristic of the secondary light generated by the material of the phosphor.

10. The method according to claim 9, wherein the power spectral density distribution over the wavelength of the detected light is determined by using the at least one detector.

11. A method of obtaining spectroscopic information on at least one object, the method comprising:
a. electrically driving at least one light source by using at least one driving unit, the light source comprising at least one light-emitting diode and at least one luminescent material for light-conversion of primary light generated by the light-emitting diode;
b. illuminating the object with illumination light generated by the light source;
c. detecting light, by using at least one detector, and, thereby, generating at least one detector signal; and
d. evaluating at the least one detector signal by using at least one evaluation unit, and deriving the spectroscopic information on the object from the at least one detector signal by using the evaluation unit, wherein the spectroscopic information on the object is derived by taking into consideration wavelength correction information, wherein the wavelength correction information is determined by using a method for calibrating the spectrometer device for obtaining the spectroscopic information on the at least one object according to claim 9.

12. A computer program comprising instructions which, when the instructions are executed by an evaluation unit of a spectrometer device, cause the evaluation unit to perform the method according to claim 11.

13. A non-transient computer-readable storage medium comprising instructions which, when the instructions are executed by an evaluation unit of a spectrometer device, cause the evaluation unit to perform the methods the method according to claim 11.
